(19) United States
(12) Patent Application Publication
(10) Pub. No.: US 2026/0214911 A1
(43) Pub. Date: Jul. 23, 2026

(54) VERTICAL NONVOLATILE MEMORY DEVICE, ELECTRONIC APPARATUS INCLUDING THE SAME, AND METHOD OF MANUFACTURING THE SAME

(71) Applicant: Samsung Electronics Co., Ltd., Suwon-si (KR)

(72) Inventors: Seokhoon CHOI, Suwon-si (KR); Minhyun LEE, Suwon-si (KR); Jinjoo PARK, Suwon-si (KR); Seonghun JANG, Suwon-si (KR); Hoseok HEO, Suwon-si (KR)

(73) Assignee: Samsung Electronics Co., Ltd., Suwon-si (KR)

(21) Appl. No.: 19/266,580

(22) Filed: Jul. 11, 2025

(30) Foreign Application Priority Data
Jan. 23, 2025 (KR) 10-2025-0010677

(51) Int. Cl. H10B 63/00

(52) U.S. Cl. CPC H10B 63/845; H10B 63/34

(57) ABSTRACT

A memory device includes a stack including alternating gate electrodes and spacers, a channel layer facing the gate electrodes and the spacers, and a charge storage layer between the channel layer and the gate electrodes and between the channel layer and the spacers. The charge storage layer includes a matrix and nanostructures discontinuously distributed in the matrix. Each of the nanostructures includes a core and a shell surrounding the core, the core includes a first dielectric material, the shell includes a second dielectric material different from the first dielectric material, and the matrix includes a third dielectric material different from the first dielectric material and the second dielectric material, and the third dielectric material includes an amorphous material with a bandgap that is greater than a bandgap of the first dielectric material.

### CROSS-REFERENCE TO RELATED APPLICATION

This application is based on and claims priority under 35 U.S.C. § 119 to Korean Patent Application No. 10-2025-0010677, filed on Jan. 23, 2025, in the Korean Intellectual Property Office, the disclosure of which is incorporated by reference herein in its entirety.

### BACKGROUND

### 1. Field

The disclosure relates to a vertical nonvolatile memory device, an electronic apparatus including the vertical nonvolatile memory device, and a method of manufacturing the vertical nonvolatile memory device.

### 2. Description of the Related Art

A nonvolatile memory (NVM) device, which functions as a semiconductor memory device, includes multiple memory cells that are configured to retain information even when power is not supplied thereto and to use the stored information again when power is supplied thereto. Nonvolatile memory devices may be used in mobile phones, digital cameras, personal digital assistants (PDAs), portable computing devices, fixed computing devices, and/or other devices.

A nonvolatile memory device may include, for example, a vertical NAND (VNAND). The VNAND is a memory device that increases integration by vertically stacking many memory cells. Various technologies are used to increase the number of stacked layers of VNAND to implement higher capacities in the same or smaller areas. For example, various technologies are used to implement VNAND, such as a method of using charge traps, a method of using phase-change materials, a method of using resistance-changing materials, and a method of using ferroelectrics. Also, various materials have been studied to improve the performance of nonvolatile memory devices, such as improving data reliability, increasing an operation speed, reducing power consumption, increasing integration and/or the like.

### SUMMARY

A vertical nonvolatile memory device including a memory cell string and an electronic apparatus including the vertical nonvolatile memory device are provided.

A method of manufacturing a three-dimensional vertical nonvolatile memory device is provided.

Additional aspects will be set forth in part in the description which follows and, in part, will be apparent from the description, or may be learned by practice of the presented embodiments of the disclosure.

According to an aspect of the disclosure, a memory device includes a plurality of memory cell strings, each of the plurality of memory cell strings including a stack including a plurality of gate electrodes and a plurality of spacers alternating in a first direction, a channel layer extending in the first direction such that the channel layer faces the plurality of gate electrodes and the plurality of spacers in a second direction intersecting the first direction, and a charge storage layer extending in the first direction such that the charge storage layer is between the channel layer and the plurality of gate electrodes in the second direction and is between the channel layer and the plurality of spacers in the second direction, the charge storage layer including a matrix extending in the first direction and a plurality of nanostructures discontinuously distributed in the matrix such that the plurality of nanostructures are spaced apart from each other, wherein each of the plurality of nanostructures includes a core and a shell surrounding the core, the core includes a first dielectric material, the shell includes a second dielectric material that is different from the first dielectric material, the matrix includes a third dielectric material that is different from the first dielectric material and the second dielectric material, and the third dielectric material includes an amorphous material with a bandgap that is greater than a bandgap of the first dielectric material.

The first dielectric material may include a first oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr).

The second dielectric material may include a second oxide different from the first oxide, the second oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr).

The third dielectric material may include at least one of an oxide, an oxynitride, or a nitride, the oxide including at least one of aluminum (Al), silicon (Si), boron (B), germanium (Ge), tin (Sn), or carbon (C), the oxynitride including at least one of aluminum (Al), silicon (Si), boron (B), germanium (Ge), tin (Sn), or carbon (C), and the nitride including at least one of aluminum (Al), silicon (Si), boron (B), germanium (Ge), tin (Sn), or carbon (C).

Each of the plurality of nanostructures may have a cross-sectional diameter of 10 nm or less.

An interval between adjacent two nanostructures, from the plurality of nanostructures, may be greater than or equal to 0.1 nm.

An average isoperimetric ratio of cross sections of the plurality of nanostructures may be greater than or equal to 4π and less than or equal to 8π.

A sum of a volume of the first dielectric material and a volume of the second dielectric material may be greater than or equal to 20% and less than or equal to 90% of a total volume of the charge storage layer.

A ratio of a volume of the second dielectric material to a sum of a volume of the first dielectric material and a volume of the second dielectric material in each of the plurality of nanostructures may be greater than 0% and less than or equal to 50%.

The core may include a mixture of the first dielectric material, the second dielectric material, and the third dielectric material, a composition ratio of the first dielectric material in the core is greater than a composition ratio of the second dielectric material in the core, the composition ratio of the first dielectric material in the core is greater than a composition ratio of the third dielectric material in the core, and a sum of the second dielectric material and the third dielectric material is less than or equal to 60% a total composition of the core.

The matrix may include a mixture of the first dielectric material, the second dielectric material, and the third dielectric material, a composition ratio of the third dielectric material in the matrix is greater than a composition ratio of the first dielectric material in the matrix, the composition ratio of the third dielectric material in the matrix is greater than a composition ratio of the second dielectric material in the matrix, and a sum of the first dielectric material and the second dielectric material is less than or equal to 60% a total composition of the matrix.

The charge storage layer may include a first surface facing the channel layer and a second surface facing the plurality of gate electrodes and the plurality of spacers, and a root mean square (RMS) value of surface roughness of the first surface and the second surface of the charge storage layer may be less than or equal to about 2 nm.

Each of the plurality of memory cell strings may further include a charge blocking layer extending in the first direction such that the charge blocking layer is between the charge storage layer and the plurality of gate electrodes in the second direction and is between the charge storage layer and the plurality of spacers in the second direction, and a charge tunneling layer extending in the first direction such that the charge tunneling layer is between the channel layer and the charge storage layer in the second direction, and each of the plurality of nanostructures may be spaced apart from the charge tunneling layer and the charge blocking layer.

The plurality of nanostructures may be spaced apart from each other in the second direction and the first direction within the matrix.

According to an aspect of the disclosure, stacking a plurality of insulating spacers and a plurality of gate electrodes in a first direction such that the plurality of gate electrodes and the plurality of insulating spacers alternate in the first direction; forming a channel hole penetrating the plurality of insulating spacers and the plurality of gate electrodes; and forming a charge storage layer and a channel layer in the channel hole such that the charge storage layer and the channel layer extend in the first direction, wherein the forming of the charge storage layer includes forming a mixture layer in the channel hole, the mixture layer including a first dielectric material, a second dielectric material which is different from the first dielectric material, and a third dielectric material which is different from the first dielectric material and the second dielectric material, and heat-treating the mixture layer to form a matrix extending in the first direction and a plurality of nanostructures distributed discontinuously in the matrix such that the plurality of nanostructures are spaced apart from each other in the first direction, each of the plurality of nanostructures includes a core and a shell surrounding the core, the core includes the first dielectric material, the shell includes the second dielectric material, the matrix includes the third dielectric material, and the third dielectric material includes an amorphous material with a bandgap that is greater than a bandgap of the first dielectric material.

The forming of the mixture layer may include forming a first layer extending continuously in the first direction, and forming a second layer extending continuously in the first direction along a surface of the first layer, and the first layer may include a mixture of the first dielectric material and the third dielectric material, and the second layer may include the second dielectric material, or the first layer includes a mixture of the second dielectric material and the third dielectric material, and the second layer may include the first dielectric material.

The forming of the mixture layer may further include forming a third layer to extend continuously in the first direction along a surface of the second layer such that the mixture layer includes two of the first layer and the second layer between the two first layers, wherein the third layer includes the mixture of the first dielectric material and the third dielectric material and the second layer includes the second dielectric material, or the third layer includes the mixture of the second dielectric material and the third dielectric material and the second layer includes the first dielectric material.

In the mixture layer, a sum of the first dielectric material and the second dielectric material is 20% to 90% of a total composition of the mixture layer, and a composition ratio of the second dielectric material in the mixture layer is less than a composition ratio of the first dielectric material in the mixture layer.

According to an aspect of the disclosure, an electronic apparatus includes a processing circuit, and a memory device including a plurality of memory cell strings, each of the plurality of memory cell strings including a stack including a plurality of gate electrodes and a plurality of spacers alternating in a first direction, a channel layer extending in the first direction such that the channel layer faces the plurality of gate electrodes and the plurality of spacers in a second direction intersecting the first direction, and a charge storage layer extending in the first direction such that the charge storage layer is between the channel layer and the plurality of gate electrodes in the second direction and is between the channel layer and the plurality of spacers in the second direction, the charge storage layer including a matrix extending in the first direction and a plurality of nanostructures discontinuously distributed in the matrix in the first direction such that the plurality of nanostructures are spaced apart from each other, wherein each of the plurality of nanostructures includes a core and a shell surrounding the core, the core includes a first dielectric material, the shell includes a second dielectric material that is different from the first dielectric material, and the matrix includes a third dielectric material that is different from the first dielectric material and the second dielectric material, and the third dielectric material includes an amorphous material with a bandgap that is greater than a bandgap of the first dielectric material.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating a memory system according to at least one example embodiment;

FIG. 2 is a block diagram illustrating an example of implementing a memory device illustrated in FIG. 1;

FIG. 3 is a block diagram illustrating a memory cell array illustrated in FIG. 1;

FIG. 4 is a diagram illustrating an equivalent circuit corresponding to a memory block, according to at least one example embodiment;

FIG. 5 is a vertical cross-sectional view schematically illustrating a structure of a memory cell string of a vertical nonvolatile memory device according to at least one example embodiment;

FIG. 6 is a horizontal cross-sectional view taken along line A-A′ of FIG. 5 and schematically illustrating a structure of a memory cell string of a vertical nonvolatile memory device according to at least one example embodiment;

FIGS. 7A to 7G illustrate a method of manufacturing a memory cell string of a vertical nonvolatile memory device, according to at least one example embodiment;

FIGS. 8 to 12 illustrate various different structures of a mixture layer;

FIG. 13 is a graph illustrating an element composition ratio of a charge storage layer;

FIG. 14 illustrates high angle annular dark field scanning transmission electron microscopy (HAADF-STEM) images showing a change in distribution of nanostructures in a matrix when the composition of a charge storage layer changes along an arrow indicated by A1 in FIG. 13;

FIG. 15 illustrates HAADF-STEM images showing a change in distribution of nanostructures in a matrix when the composition of a charge storage layer changes along an arrow indicated by A2 in FIG. 13;

FIG. 16 illustrates HAADF-STEM images showing a change in distribution of nanostructures in a matrix when the composition of a charge storage layer changes along an arrow indicated by A3 in FIG. 13;

FIG. 17 is a graph illustrating distributions of cross-sectional areas of nanostructures according to a change in composition of a charge storage layer;

FIG. 18 is a graph illustrating a change in isoperimetric ratio of cross-sectional shapes of nanostructures according to a change in composition of a charge storage layer;

FIG. 19 is an image illustrating surface roughness of a charge storage layer after heat treatment;

FIG. 20 is a vertical cross-sectional view schematically illustrating a structure of a memory cell string of a vertical nonvolatile memory device according to another embodiment;

FIG. 21 is a conceptual diagram schematically illustrating a device architecture that may be applied to an electronic apparatus including a memory device, according to at least one example embodiment; and

FIG. 22 is a schematic diagram illustrating a neuromorphic apparatus including a memory device, according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a vertical nonvolatile memory device, an electronic apparatus including the vertical nonvolatile memory device, and a method of manufacturing the vertical nonvolatile memory device are described in detail with reference to the attached drawings. In the following drawings, the same reference numerals refer to the same components, and a size of each component in the drawings may be exaggerated for the sake of clear and convenient description. Also, the following embodiments to be described are merely examples, and various modifications may be made from the embodiments.

Hereinafter, what is described as an “upper portion/lower portion” or “over and above/lower and under” may also include not only on/beneath but also above and above/lower and under”. Singular expressions include plural expressions unless the context clearly indicates otherwise. In addition, when a portion “includes” a certain component, this means that other components may be further included rather than excluding other components unless specifically stated to the contrary.

Use of the term “the” and similar reference terms may correspond to both the singular and the plural. Steps constituting a method may be performed in any suitable order unless there is a clear statement that the steps should be performed in the order described or contrary to the order and are not limited thereto. Additionally, although the terms “first,” “second,” “third,” etc., may be used herein to describe various elements, components, regions, layers, and/or sections, these elements, components, regions, layers, and/or sections, should not be limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

Also, terms, such as “unit”, “portion”, and “module”, and/or terms describing a unit that processes at least one function or operation, may be implemented by processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Connection or connection members of lines between configuration elements illustrated in the drawings represent functional connections and/or physical or circuit connections and may be represented as alternative or additional various functional connections, physical connections, or circuit connections in an actual apparatus.

Use of all examples or all example terms is merely for describing technical ideas in detail, and the scope of claims is not limited by the examples or the example terms unless limited by the claims.

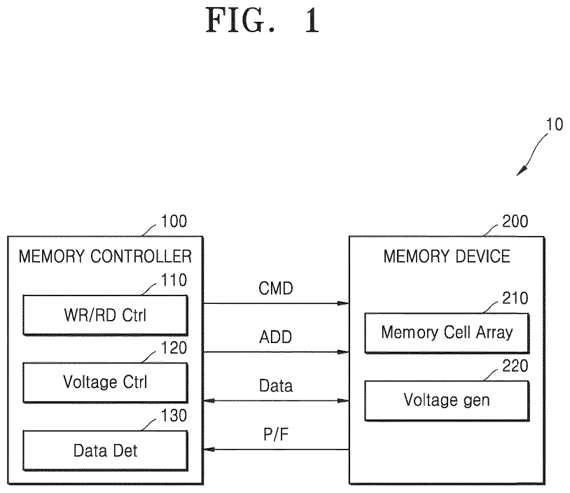

FIG. 1 is a block diagram illustrating a memory system according to at least one example embodiment. Referring to FIG. 1, a memory system 10 according to at least one example embodiment may include a memory controller 100 and a memory device 200. The memory controller 100 is configured to perform a control operation on the memory device 200, and for example, the memory controller 100 may perform a program operation (or a write operation), a read operation, and an erase operation on the memory device 200 by providing an address ADD and a command CMD to the memory device 200. Also, data for the program operation and read data may be transmitted and received between the memory controller 100 and the memory device 200. The memory device 200 may provide pass/fail (P/F) signals to the memory controller 100 according to a read result of the read data, and the memory controller 100 may control write and read operations of a memory cell array 210 by referring to the pass/fail signals.

The memory device 200, according to some example embodiments, includes the memory cell array 210 and a voltage generator 220. The memory cell array 210 may include a plurality of memory cells arranged in regions where a plurality of word lines intersect a plurality of bit lines. The memory cell array 210 may include nonvolatile memory cells that are configured to store data in a nonvolatile manner, and the memory cell array 210, which functions as nonvolatile memory cells, may include flash memory cells, such as a NAND flash memory cell array and/or a NOR flash memory cell array. Hereinafter, example embodiments are described in detail by assuming that the memory cell array 210 includes a flash memory cell array and, accordingly, the memory device 200 is a nonvolatile memory device.

The memory controller 100, according to some example embodiments, includes a write/read controller 110, a voltage controller 120, and a data determination unit 130.

The write/read controller 110 is configured to generate the address ADD and the command CMD for performing a program operation, a read operation, and an erase operation on the memory cell array 210. Also, the voltage controller 120 may generate a voltage control signal for controlling at least one voltage level used in the nonvolatile memory device 200. For example, the voltage controller 120 may generate a voltage control signal for controlling a voltage level of a word line for reading data from the memory cell array 210 or programming data into the memory cell array 210.

The data determination unit 130 is configured perform a determination operation on the data read from the memory device 200. For example, by determining the data read from the memory cells, the number of on-cells and/or off-cells among the memory cells may be determined. In an example of an operation, when a program is executed for a plurality of memory cells, a state of the data of the memory cells may be determined by using a preset read voltage, and accordingly, whether the program is completed normally for all cells may be determined.

As described above, the memory cell array 210 may include nonvolatile memory cells, and for example, the memory cell array 210 may include flash memory cells. Also, the flash memory cells may be implemented in various forms, and for example, the memory cell array 210 may include three-dimensional (or vertical) NAND (VNAND) memory cells.

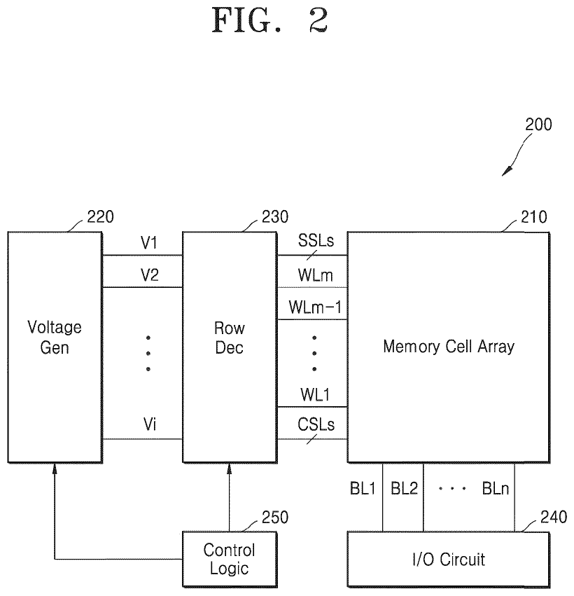

FIG. 2 is a block diagram illustrating an example of implementing the memory device 200 illustrated in FIG. 1. Referring to FIG. 2, the memory device 200 may further include a row decoder 230, an input/output circuit 240, and a control logic 250.

The memory cell array 210 may be connected to one or more string select lines SSLs, a plurality of word lines WL1 to WLm, and one or more common source lines CSLs, and may also be connected to a plurality of bit lines BL1 to BLn. The voltage generator 220 is configured to generate one or more word line voltages V1 to Vi, and the word line voltages V1 to Vi may be provided to the row decoder 230. Signals for program/read/erase operations may be applied to the memory cell array 210 through the plurality of bit lines BL1 to BLn.

Also, data to be programmed may be provided to the memory cell array 210 through the input/output circuit 240, and the read data may be provided to the outside (for example, the memory controller 100) through the input/output circuit 240. The control logic 250 may provide various control signals related to a memory operation to the row decoder 230 and the voltage generator 220.

The word line voltages V1 to Vi may be provided to various lines SSLs, WL1 to WLm, and CSLs according to a decoding operation of the row decoder 230. For example, the word line voltages V1 to Vi may include a string select voltage, word line voltages, and a ground select voltage, the string select voltage may be provided to the one or more string select lines SSLs, the word line voltage may be provided to the plurality of word lines WL1 to WLm, and the ground select voltage may be provided to the one or more common source lines CSLs.

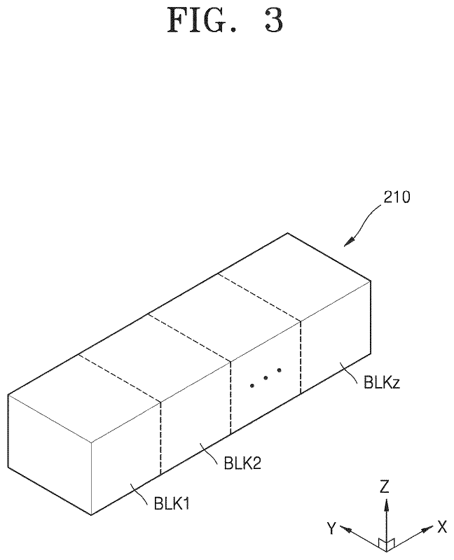

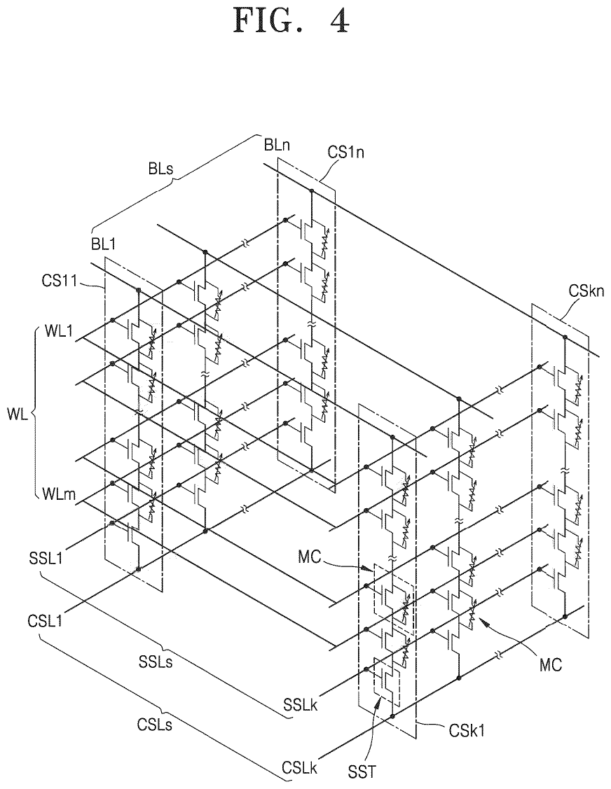

FIG. 3 is a block diagram illustrating the memory cell array 210 illustrated in FIG. 1. Referring to FIG. 3, the memory cell array 210 may include a plurality of memory blocks BLK1 to BLKz. A memory block BLK (one of the plurality of memory blocks BLK1 to BLKz) may have a three-dimensional structure (or a vertical structure). For example, the memory block BLK may include structures extending in a first direction to a third direction. For example, the memory block BLK may include a plurality of memory cell strings extending in the first direction (the Z direction). Therefore, the plurality of memory cell strings may each have a three-dimensional vertical structure. In this respect, the memory device 200 may be a three-dimensional vertical nonvolatile memory device. The plurality of memory cell string may each be connected to a bit line BL, a string select line SSL, word lines WL, and a common source line CSL. Therefore, the plurality of memory blocks BLK1 to BLKz may be connected to a plurality of bit lines BL, a plurality of string select lines SSLs, a plurality of word lines WL, and a plurality of common source lines CSLs. The plurality of memory blocks BLK1 to BLKz are described in more detail with reference to FIG. 4.

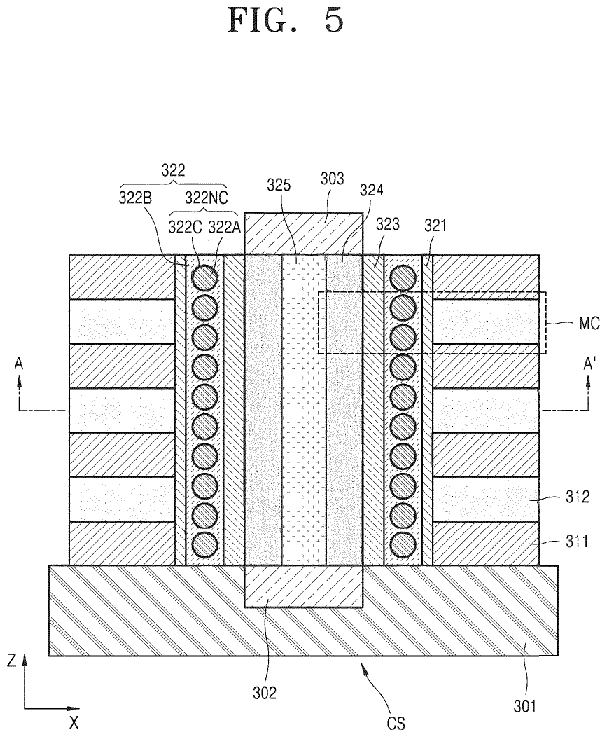

FIG. 4 is a diagram illustrating an equivalent circuit corresponding to an example of a memory block, according to at least one example embodiment. For example, the memory block illustrated in FIG. 4 may be one of the plurality of memory blocks BLK1 to BLKz of the memory cell array 210 illustrated in FIG. 3 is illustrated in FIG. 4. FIG. 5 is a vertical cross-sectional view schematically illustrating a structure of a memory cell string of a vertical nonvolatile memory device according to at least one example embodiment.

Referring to FIG. 3 and FIG. 4, the plurality of memory blocks BLK1 to BLKz may each include a plurality of memory cell strings CS11 to CSkn. The plurality of memory cell strings CS11 to CSkn may be two-dimensionally arranged in a row direction and a column direction to form rows and columns. The plurality of memory cell strings CS11 to CSkn may each include a plurality of memory cells MC and a string select transistor SST. The plurality of memory cells MC and the string select transistor SST of each of the plurality of memory cell strings CS11 to CSkn may be stacked in a height direction.

Rows of the plurality of memory cell strings CS11 to CSkn may be respectively connected to different string select lines SSL1 to SSLk. For example, the string select transistors SST of the memory cell strings CS11 to CS1n may be commonly connected to the string select line SSL1. The string select transistors SST of the memory cell strings CSk1 to CSkn may be commonly connected to the string select line SSLk.

Also, columns of the plurality of memory cell strings CS11 to CSkn may be respectively connected to different bit lines BL1 to BLn. For example, the memory cells MC and string select transistors SST of the memory cell strings CS11 to CSk1 may be commonly connected to the bit line BL1, and the memory cells MC and string select transistors SST of the memory cell strings CS1n to CSkn may be commonly connected to the bit line BLn.

Also, rows of the memory cell strings CS11 to CSkn may be connected to different common source lines CSL1 to CSLk. For example, the string select transistors SST of the memory cell strings CS11 to CS1n may be commonly connected to the common source line CSL1, and the string select transistors SST of the memory cell strings CSk1 to CSkn may be commonly connected to the common source line CSLk.

The memory cells MC located at the same height from a substrate (or the string select transistors SST) may be commonly connected to one word line WL, and memory cells MC located at different heights may be connected to different word lines WL1 to WLm.

The memory block illustrated in FIG. 4 is an example. The technical idea of the disclosure is not limited to the memory block illustrated in FIG. 4. For example, the number of rows of the plurality of memory cell strings CS11 to CSkn may be increased or decreased. As the number of rows of the plurality of memory cell strings CS11 to CSkn is changed, the number of string selection lines SSL1 to SSLk connected to the rows of the number of plurality of memory cell strings CS11 to CSkn, and the number of memory cell strings CS11 to CSkn connected to one bit line may also be changed. As the number of rows of the plurality of memory cell strings CS11 to CSkn is changed, the number of common source lines CSL1 to CSLk connected to the rows of the plurality of memory cell strings CS11 to CSkn may also be changed. Also, the number of columns of the plurality of memory cell strings CS11 to CSkn may be increased or decreased. As the number of rows of the plurality of memory cell strings CS11 to CSkn is changed, the number of bit lines BL1 to BLn connected to the rows of the plurality of memory cell strings CS11 to CSkn, and the number of plurality of memory cell strings CS11 to CSkn connected to one string select line SSL may also be changed.

Heights of the plurality of memory cell string CS11 to CSkn may increase or decrease. For example, the number of memory cells MC stacked in each of the plurality of memory cell string CS11 to CSkn may be increased or decreased. As the number of memory cells MC stacked in each of the plurality of memory cell strings CS11 to CSkn is changed, the number of word lines WL may also be changed. For example, the number of string select transistors provided to each of the plurality of memory cell string CS11 to CSkn may be increased. As the number of string select transistors provided to each of the plurality of memory cell strings CS11 to CSkn is changed, the number of string select lines or common source lines may also be changed. When the number of string select transistors is increased, the string select transistors may be stacked in the same form as the plurality of memory cells MC.

For example, write and read operations may be performed in units of rows of the memory cell strings CS11 to CSkn. The plurality of memory cell strings CS11 to CSkn may be selected in units of one row by the common source lines CSLs, and the plurality of memory cell strings CS11 to CSkn may be selected in units of one row by the string select lines SSLs. In addition, in the selected row of the plurality of memory cell string CS11 to CSkn, write and read operations may be performed in units of a page. For example, a page may be one row of the plurality of memory cells MC connected to one word line WL. In the selected row of the plurality of memory cell string CS11 to CSkn, the plurality of memory cells MC may be selected in units of a page by the word lines WL.

In addition, the plurality of memory cells MC in each of the plurality of memory cell string CS11 to CSkn may correspond to a circuit in which a transistor and a resistor are connected in parallel. For example, referring to FIG. 5, the memory cell string CS may include a stacking comprising a plurality of insulating spacers 311 and a plurality of gate electrodes 312 that are alternately stacked in a first direction (e.g., a vertical direction or the Z direction) perpendicularly intersecting a second direction (the X direction). The plurality of insulating spacers 311 and the plurality of gate electrodes 312 may extend in a horizontal direction, that is, the second direction. The plurality of gate electrodes 312 may each be connected to the word line WL, or each of the plurality of gate electrodes 312 may itself be the word line WL.

The plurality of insulating spacers 311 may each include one or more insulating dielectric materials, such as a silicon oxide, an aluminum oxide, a silicon nitride, and/or a combination thereof, but are not limited thereto. The plurality of gate electrodes 312 may each include a metal having relatively high electrical conductivity, a conductive oxide, a conductive metal nitride, silicon doped with an impurity, a two-dimensional conductive material, and/or a combination thereof. For example, the plurality of gate electrodes 312 may each include at least one conductive material among gold (Au), tungsten (W), molybdenum (Mo), ruthenium (Ru), titanium (Ti), platinum (Pt), polysilicon, TiN, TaN, WN, NbN, a metallic two-dimensional material, and/or a combination thereof. The metallic two-dimensional material may include at least one of graphene, TaS₂, TaSe₂, NbS₂, NbSe₂, PdTe₂, PtTe₂, NbTe₂, TiSe₂, VSe₂, AuSe, MoTe₂, and/or the like. The conductive oxide may include, for example, at least one of indium tin oxide (ITO), indium zinc oxide (IZO), indium zinc oxide (IZO), and/or the like. In addition, the plurality of gate electrodes 312 may each include various other conductive materials.

Also, the memory cell string CS may include a channel hole that penetrates the plurality of insulating spacers 311 and the plurality of gate electrodes 312 in the first direction. A plurality of layers may be provided within the channel hole to form a channel and a resistor. For example, the memory cell string CS may further include an insulating support 325 provided at the center of the channel hole and extending continuously in the first direction, a channel layer 324 surrounding the insulating support 325 and extending continuously in the first direction, a charge tunneling layer 323 surrounding the channel layer 324 and extending continuously in the first direction, a charge storage layer 322 surrounding the charge tunneling layer 323 and extending continuously in the first direction, and a charge blocking layer 321 surrounding the charge storage layer 322 and extending continuously in the first direction.

The channel layer 324 may face the plurality of gate electrodes 312 and the plurality of insulating spacers 311 in a second direction (e.g., a horizontal direction; and/or the X and/or Y directions). The charge storage layer 322 may be provided between the channel layer 324 and the plurality of gate electrodes 312 in the second direction and between the channel layer 324 and the plurality of insulating spacers 311 in the second direction. The charge tunneling layer 323 may be provided between the channel layer 324 and the charge storage layer 322 in the second direction. Also, the charge blocking layer 321 may be provided between the charge storage layer 322 and the plurality of gate electrodes 312 in the second direction and between the charge storage layer 322 and the plurality of insulating spacers 311 in the second direction.

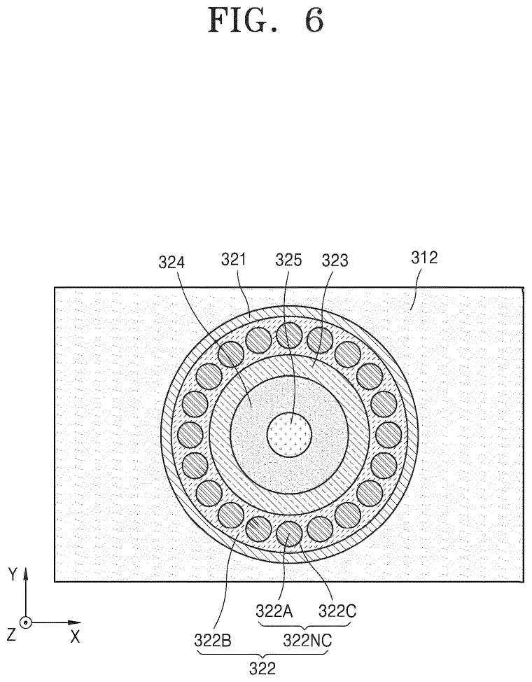

FIG. 6 is a horizontal cross-sectional view taken along line A-A′ of FIG. 5 and schematically illustrating a structure of a memory cell string of a vertical nonvolatile memory device according to at least one example embodiment. Referring to FIG. 6, the insulating support 325, the channel layer 324, the charge tunneling layer 323, the charge storage layer 322, and the charge blocking layer 321 may be sequentially provided in a concentric shape from the center. The channel layer 324 may have a cylindrical shape surrounding the insulating support 325, the charge tunneling layer 323 may have a cylindrical shape surrounding the channel layer 324, the charge storage layer 322 may have a cylindrical shape surrounding the charge tunneling layer 323, and the charge blocking layer 321 may have a cylindrical shape surrounding the charge storage layer 322. The plurality of gate electrodes 312 may surround the charge blocking layer 321. As illustrated in FIGS. 5 and 6, the plurality of insulating spacers 311 and the plurality of gate electrodes 312 may be alternately stacked in the first direction while surrounding the charge blocking layer 321.

To this end, the charge blocking layer 321 may be conformally deposited on the plurality of insulating spacers 311 and the plurality of gate electrodes 312 and may extend in the first direction. The charge storage layer 322 may be conformally deposited along a surface of the charge blocking layer 321 and may extend in the first direction. The charge tunneling layer 323 may be conformally deposited along a surface of the charge storage layer 322 and may extend in the first direction. The channel layer 324 may be conformally deposited along a surface of the charge tunneling layer 323 and may extend in the first direction. The Insulating support 325 may be provided to fill the remaining space at the center of the channel hole and may extend in the vertical direction.

As a result, the channel layer 324 may have a form extending in the first direction by facing the plurality of insulating spacers 311 and the plurality of gate electrodes 312. Also, the charge storage layer 322 may have a form extending in the first direction between the channel layer 324 and the plurality of gate electrodes 312 and between the channel layer 324 and the plurality of insulating spacers 311. The charge tunneling layer 323 may have a form extending in the first direction between the channel layer 324 and the charge storage layer 322. The charge blocking layer 321 may have a form extending in the first direction between the charge storage layer 322 and the plurality of gate electrodes 312 and between the charge storage layer 322 and the plurality of insulating spacers 311.

The memory cell string CS may be provided on a substrate 301. Although FIG. 5 illustrates only one memory cell string CS for the sake of convenience and clarity of illustration, the plurality of memory cell strings CS may be two-dimensionally provided on the substrate 301. The substrate 301 may be a semiconductor substrate. For example, the substrate 101 may include a single crystal silicon substrate, a compound semiconductor substrate, or a silicon on insulator (SOI) substrate but is not limited thereto. Also, the substrate 301 may further include, for example, an impurity region formed by doping, an electronic device such as a transistor, or a peripheral circuit that selects and controls memory cells storing data.

A source 302 may be provided on a lower surface of the channel layer 324. The source 302 may include a doped semiconductor material. For example, the source 302 may be a section of the substrate 301 doped through, e.g., doping ion implantation. The source 302 may be electrically connected to a lower portion of the channel layer 324. For example, the source 302 may be provided along an upper surface of the substrate 301 facing the channel layer 324. The source 302 may also be embedded in the substrate 301. The common source line CSL may be connected to the source 302.

Also, a drain 303 may be provided on an upper surface of the memory cell string CS to cover at least an upper surface of the channel layer 324. The drain 303 may include a doped semiconductor material. The drain 303 may be electrically connected to an upper portion of the channel layer 324. The bit line BL may be connected to the drain 303.

As indicated by a dashed box in FIG. 5, one gate electrode 312, and a part of the charge blocking layer 321, a part of the charge storage layer 322, a part of the charge tunneling layer 323, and a part of the channel layer 324, which are adjacent to the one gate electrode 312 in a horizontal direction, that is, in the second direction, may form one memory cell MC. In this structure, when a preset voltage is applied to the gate electrode 312 of the memory cell MC, a channel may be formed in an internal region of a part of the channel layer 324 facing the gate electrode 312 in the second direction, charges flowing between the source 302 and the drain 303 pass through the charge tunneling layer 323 to be captured in the charge storage layer 322, and accordingly, information may be stored.

The channel layer 324 may include a semiconductor material. The channel layer 324 may include, for example, at least one Si, Ge, SiGe, a III-V group semiconductor material, an oxide semiconductor, a nitride semiconductor, an oxynitride semiconductor, a two-dimensional (2D) semiconductor material, a quantum dot, an organic semiconductor; and/or the like. The oxide semiconductor may include, for example, InGaZnO and/or the like. The two-dimensional semiconductor material may include, for example, transition metal dichalcogenide (TMD), graphene, black phosphorous, and/or the like, and the quantum dot may include a colloidal quantum dot (QD), a nanocrystal structure, and/or the like. The two-dimensional semiconductor material may refer to a semiconductor material having a two-dimensional crystal structure and may have a monolayer or multilayer structure. The two-dimensional semiconductor material has excellent electrical properties, and even when a thickness of the two-dimensional semiconductor material is reduced to a nanoscale, the two-dimensional semiconductor material maintains high mobility without a great change in property, and accordingly, the two-dimensional semiconductor material may be applied to various devices. Each layer constituting the two-dimensional semiconductor material may have a thickness at an atomic level. The channel layer 324 may include, for example, two-dimensional semiconductor material having 1 to 10 layers.

The channel layer 324 may further include a dopant. Here, the dopant may include a p-type dopant or an n-type dopant. In at least some examples,, p-type dopant may include a group III element, such as B, Al, Ga, or In, and the n-type dopant may include a group V element, such as P, As, or Sb.

The charge tunneling layer 323 is a layer configured such that charge tunneling occurs between the channel layer 324 and the charge storage layer 322. The charge tunneling layer 323 may include an insulating material, such as silicon oxide (SiO₂) and/or a metal oxide but is not limited thereto.

The charge blocking layer 321 prevents or reduces charges from leaking to the gate electrode 312 and the insulating spacer 311 beyond the charge storage layer 322. The charge blocking layer 321 may include an insulating material, such as at least one of silicon oxide (SiO), aluminum oxide (AlO), magnesium oxide (MgO), aluminum nitride (AlN), and/or gallium nitride (GaN) but is not limited thereto. Although FIGS. 5 and 6 illustrate that the charge blocking layer 321 has a single layer for the sake of convenience and clarity of illustration, the charge blocking layer 321 may have a multilayer structure including different materials.

Charges (for example, electrons or holes) in the channel layer 324 may be introduced into the charge storage layer 322 through the charge tunneling layer 323 by a tunneling effect or the like. The charges introduced into the charge storage layer 322 may be trapped within the charge storage layer 322. According to at least one example embodiment, the charge storage layer 322 may include a matrix 322B forming a thin layer extending in the first direction and a plurality of nanostructures 322NC dispersedly distributed within the matrix 322B. The plurality of nanostructures 322NC may be spaced apart from each other and distributed discontinuously within the matrix 322B. To this end, each of the plurality of nanostructures 322NC may be completely surrounded by the matrix 322B. Therefore, the plurality of nanostructures 322NC may not be in direct contact with the charge tunneling layer 323 and the charge blocking layer 321 adjacent to the charge storage layer 322. In other words, the plurality of nanostructures 322NC may each be spaced apart from the charge tunneling layer 323 and the charge blocking layer 321 adjacent to the charge storage layer 322. The plurality of nanostructures 322NC may each function as an independent charge trap media.

The plurality of nanostructures 322NC may each have a core-shell structure. In other words, the plurality of nanostructures 322NC may each include a core 322A and a shell 322C surrounding an outer surface of the core 322A. The core 322A and the shell 322C may include different metal oxide dielectric materials. In other words, the core 322A may include a first dielectric material of a metal oxide, and the shell 322C may include a second dielectric material of a metal oxide that is different from the first dielectric material. The first dielectric material may include an oxide of at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), and/or strontium (Sr). The second dielectric material may include at least one metal oxide, which is different from the first dielectric material, among oxides of at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), and/or strontium (Sr).

The matrix 322B may have a band gap that is greater than a band gap of the first dielectric material. Also, a conduction band offset (CBO) of the matrix 322B with respect to the charge tunneling layer 323 may be greater than a CBO of the first dielectric material with respect to the charge tunneling layer 323. Also, a valence band offset (VBO) of the matrix 322B with respect to the charge tunneling layer 323 may be greater than a VBO of the first dielectric material with respect to the charge tunneling layer 323. The matrix 322B may include a glassy or amorphous third dielectric material that satisfies the conditions described above and may form a molecular structure in the form of a chain and/or bridge. For example, the third dielectric material of the matrix 322B may include a group 3 or group 4 element. The third dielectric material of the matrix 322B may be different from the first dielectric material and the second dielectric material and may have a band gap that is greater than a band gap of the first dielectric material.

The third dielectric material may include at least one of an oxide of aluminum (Al), silicon (Si), boron (B), germanium (Ge), tin (Sn), carbon (C), and/or combination thereof, an oxynitride of aluminum (Al), silicon (Si), boron (B), germanium (Ge), tin (Sn), carbon (C), and/or combination thereof, and/or a nitride of aluminum (Al), silicon (Si), boron (B), germanium (Ge), tin (Sn), carbon (C), and/or combination thereof. The third dielectric material of the matrix 322B may be different from the first dielectric material and the second dielectric material. For example, when either the first dielectric material or the second dielectric material includes an aluminum oxide, the third dielectric material of the matrix 322B may include a material that is different from the aluminum oxide. In addition, when the third dielectric material of the matrix 322B includes an oxynitride of aluminum (Al), silicon (Si), boron (B), germanium (Ge), tin (Sn), or carbon (C), the content of oxygen in the oxynitride may be greater than or equal to about 10 at %. When the third dielectric material of the matrix 322B includes a nitride of aluminum (Al), silicon (Si), boron (B), germanium (Ge), tin (Sn), or carbon (C), some of charges may also be trapped within the matrix 322B.

As described above, the charge storage layer 322 may include the first dielectric material, the second dielectric material, and the third dielectric material. In the charge storage layer 322, the first dielectric material may have a plurality of spherical shapes or near-spherical shapes spaced apart from each other, and the second dielectric material may surround a surface of the first dielectric material. The third dielectric material may form a matrix. The first dielectric material and the second dielectric material may be discontinuously distributed within the third dielectric material. The matrix 322B and the plurality of nanostructures 322NC of the charge storage layer 322 may be formed by spinodal decomposition and nucleation growth through heat treatment of a mixture of the first dielectric material, the second dielectric material, and the third dielectric material.

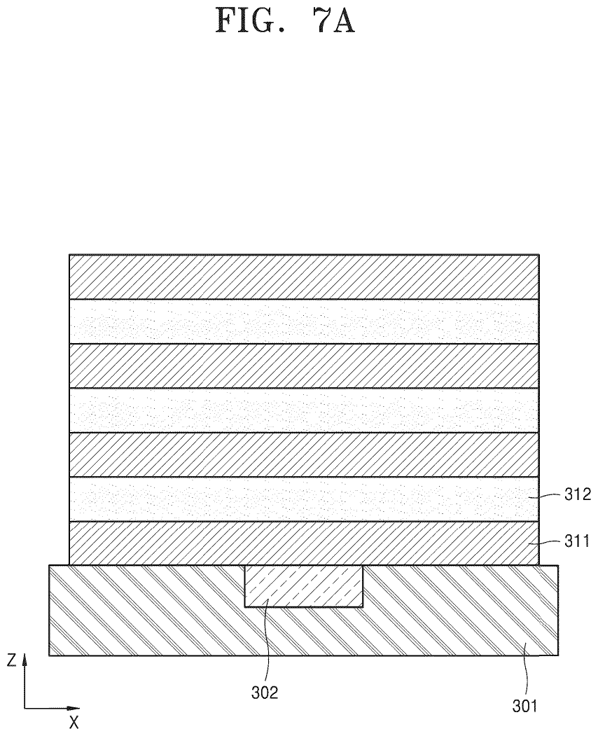

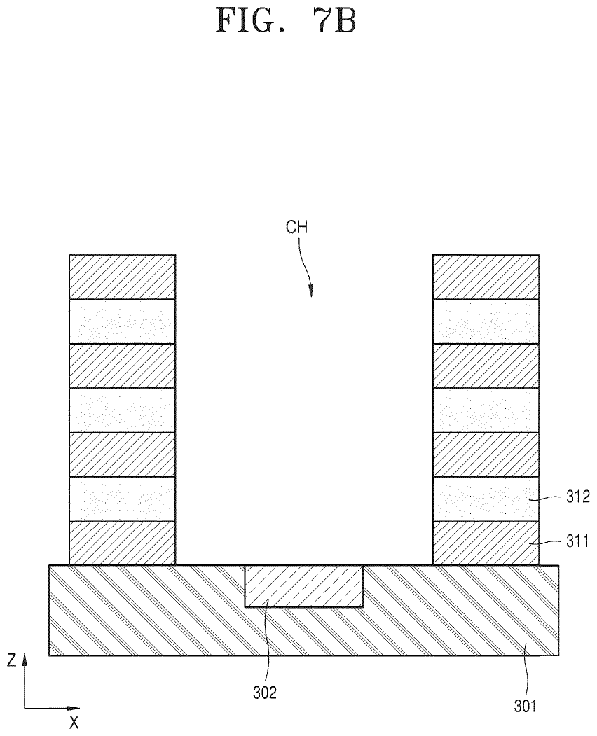

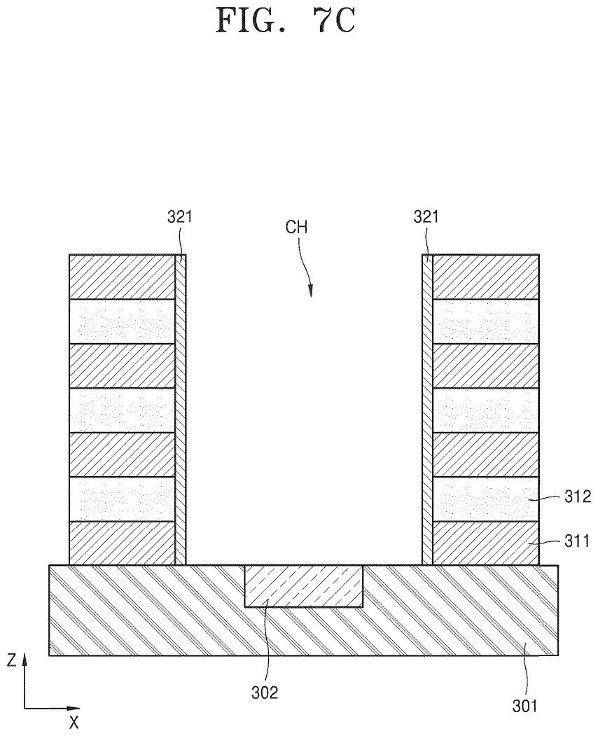

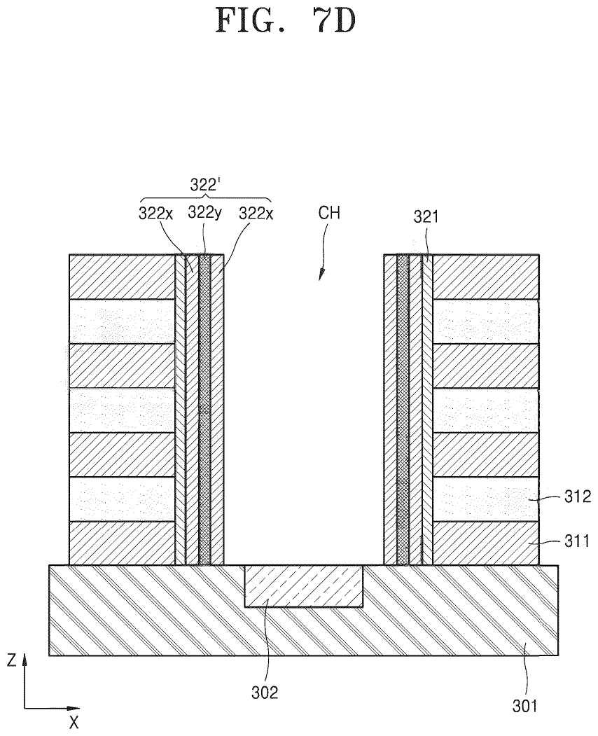

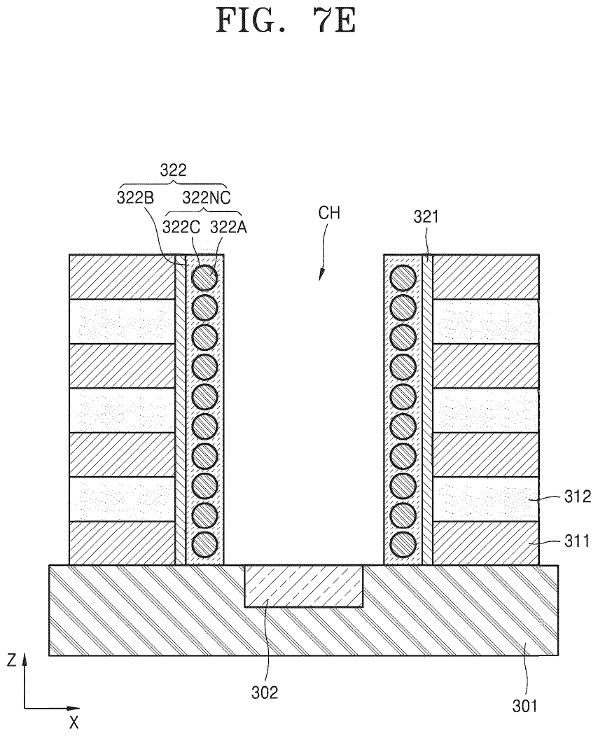

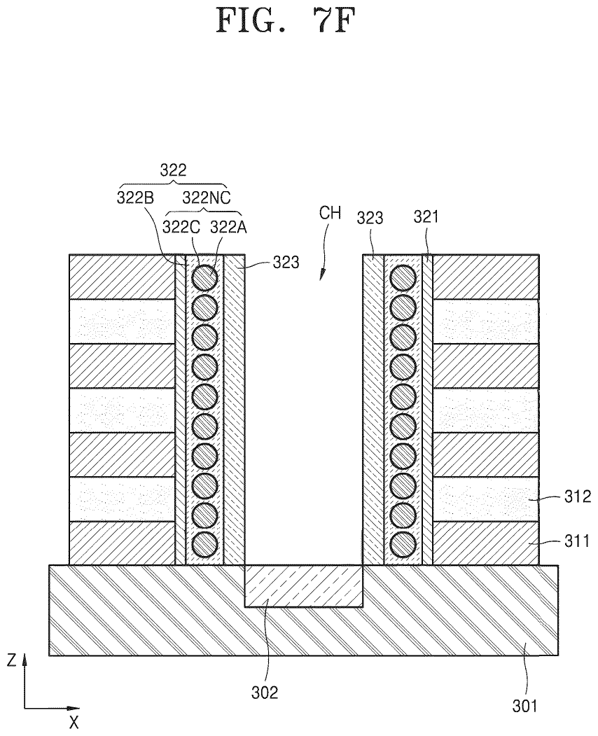

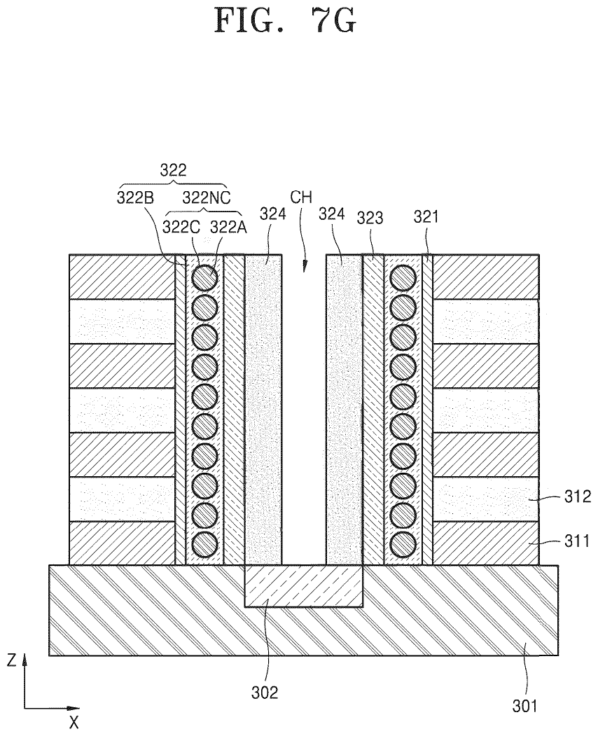

FIGS. 7A to 7G illustrate a method of manufacturing the memory cell string CS of a vertical nonvolatile memory device, according to at least one example embodiment.

Referring to FIG. 7A, a plurality of insulating spacers 311 and a plurality of gate electrodes 312 may be alternately stacked in a first direction on a substrate 301 in which a source 302 is formed. For example, the insulating spacer 311 may be first formed on an upper surface of the substrate 301, the gate electrode 312 and the insulating spacer 311 may be alternately formed multiple times, and then an upper most insulating spacer 311 may be finally formed on the final gate electrode 312.

Referring to FIG. 7B, a channel hole CH penetrating the center of the plurality of insulating spacers 311 and the plurality of gate electrodes 312 may be formed. For example, the center of the plurality of insulating spacers 311 and the plurality of gate electrodes 312 may be etched such that upper surfaces of the substrate 301 and the source 302 are exposed.

Referring to FIG. 7C, for example, a charge blocking layer 321 extending continuously in the first direction along sidewalls of the plurality of insulating spacers 311 and the plurality of gate electrodes 312 within a channel hole CH may be conformally formed through atomic layer deposition (ALD). The charge blocking layer 321 may be formed by depositing at least one of silicon oxide (SiO), aluminum oxide (AlO), magnesium oxide (MgO), aluminum nitride (AlN), and/or gallium nitride (GaN), on an inner wall of the channel hole CH through the ALD.

Referring to FIG. 7D, a mixture layer 322′ extending continuously in the first direction along a surface of the charge blocking layer 321 may be formed. The mixture layer 322′ may include a first layer 322x and a second layer 322y. The second layer 322y may be inserted into the first layer 322x. For example, in at least one example, the first layer 322x may include a mixture of a first dielectric material and a third dielectric material, and the second layer 322y may include a second dielectric material. In another at least one example, the first layer 322x may include a mixture of the second dielectric material and the third dielectric material, and the second layer 322y may include the first dielectric material. For example, the first layer 322x may be deposited to extend continuously in the first direction along a surface of the charge blocking layer 321 by using an ALD method, the second layer 322y may be deposited to extend continuously in the first direction along a surface of the first layer 322x by using the ALD method, and the first layer 322x may be deposited to extend continuously in the first direction along a surface of the second layer 322y by using the ALD method. When depositing the first layer 322x, a first cycle of depositing the first dielectric material or the second dielectric material and a second cycle of depositing the third dielectric material may be alternately performed. Alternatively, a performing ratio of the first cycle and the second cycle may be adjusted depending on the composition of the first dielectric material and the third dielectric material or the composition of the second dielectric material and the third dielectric material.

A ratio of the sum of the first dielectric material and the second dielectric material within the mixture layer 322′ may be about 20% to about 90% of the entire mixture layer 322′. In other words, when the amount of the first dielectric material is referred to as A, the amount of the second dielectric material is referred to as B, and the amount of the third dielectric material is referred to as C, (A+B)/(A+B+C) may be 0.2 to 0.9. Also, a composition ratio of the second dielectric material may be less than or equal to a composition ratio of the first dielectric material. In other words, B/(A+B) may be less than or equal to 0.5.

Referring to FIG. 7E, the charge storage layer 322 may be formed by heat-treating the mixture layer 322′. The heat-treating temperature may be, for example, 800° C. to 1400° C., or 900° C. to 1300° C., or 1000° C. to 1200° C., or 1000° C. to 1100° C. In the heat-treating process, spinodal decomposition may occur in the mixture layer 322′, and further, a nanostructure 322NC may be formed by nucleation growth. In other words, the mixture layer 322′ may be a kind of solid solution, the first dielectric material within the mixture layer 322′ may be separated and aggregated due to thermodynamic instability of the solid solution during the heat treatment, and accordingly, a core 322A having a spherical shape or a shape close to a spherical shape may be formed, and the second dielectric material may aggregate around the core 322A to form a shell 322C. The amorphous third dielectric material including a group 3 element or group 4 element may diffuse throughout the mixture layer 322′ to form a matrix 322B. The core 322A and the shell 322C may be mainly determined according to composition ratios of the first dielectric material and the second dielectric material. For example, the first dielectric material having a relatively great composition ratio among the first dielectric material and the second dielectric material becomes the core 322A during the heat treatment, and the second dielectric material having a relatively small composition ratio becomes the shell 322C.

As a result, a plurality of nanostructures 322NC may be distributed to be discontinuously spaced apart along the first direction within the matrix 322B. According to at least one example embodiment, a cross-sectional diameter of the nanostructure 322NC including the core 322A and the shell 322C may be less than or equal to about 10 nm, for example, about 5 nanometers (nm) to about 7 nm. Also, the smallest interval between adjacent two nanostructures 322NC may be greater than or equal to about 0.1 nm.

Referring to FIG. 7F, a charge tunneling layer 323 extending continuously in the first direction along a surface of the charge storage layer 322 may be formed. For example, the charge tunneling layer 323 may be formed by conformally depositing silicon oxide (SiO₂) or another metal oxide along the surface of the charge storage layer 322 by using an ALD method.

Referring to FIG. 7G, a channel layer 324 extending continuously in the first direction along a surface of the charge tunneling layer 323 may be formed. For example, the channel layer 324 may be formed by conformally depositing a semiconductor material along the surface of the charge tunneling layer 323 by an ALD method. Although not illustrated in FIG. 7G, after the channel layer 324 is formed, a channel hole CH inside the channel layer 324 may be filled with an insulating dielectric material to form an insulating support 325. However, the embodiment is not limited thereto, and the channel hole CH may be left as an empty space. In this case, the channel hole CH may also be filled with air.

In FIG. 7E, it is described that the heat treatment process for spinodal decomposition is performed immediately after forming the mixture layer 322′. However, the example embodiments are not limited thereto. The heat treatment process for spinodal decomposition may be performed at any stage after the mixture layer 322′ is formed. For example, the heat treatment process for spinodal decomposition may be performed after the charge tunneling layer 323 illustrated in FIG. 7F is formed, or after the channel layer 324 illustrated in FIG. 7G is formed. In this case, the mixture layer 322′ may remain immediately after the charge tunneling layer 323 or the channel layer 324 is formed, and the charge storage layer 322 may be formed through a heat treatment process after the charge tunneling layer 323 or the channel layer 324 is formed.

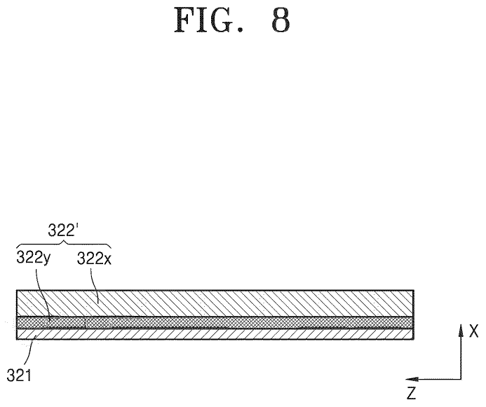

Also, although FIG. 7D illustrates that the second layer 322y is located near the inner center of the mixture layer 322′, the embodiment is not limited thereto. The mixture layer 322′ may be formed in various other ways. For example, FIGS. 8 to 12 illustrate various other structures of the mixture layer 322′.

Referring to FIG. 8, the second layer 322y may be formed before the first layer 322x. For example, the second layer 322y may be formed along a surface of the charge blocking layer 321, and the first layer 322x may be formed along a surface of the second layer 322y.

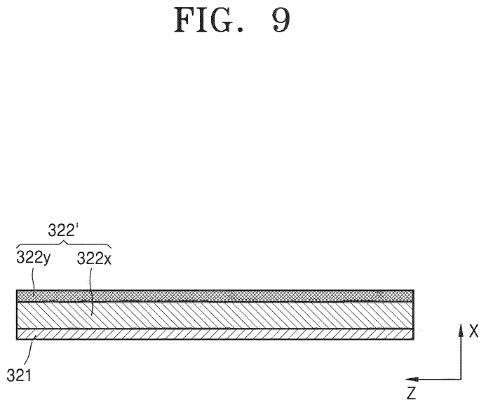

Referring to FIG. 9, the second layer 322y may be formed last. For example, the first layer 322x may be first formed along the surface of the charge blocking layer 321, and then the second layer 322y may be formed along the surface of the first layer 322x. The first layer 322x is not further formed on the surface of the second layer 322y.

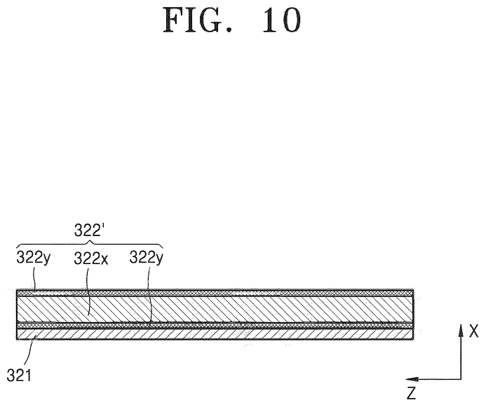

In the examples illustrated in FIGS. 8 and 9, the second layer 322y may be provided on only one of the two side surfaces of the mixture layer 322′ in the second direction. However, the embodiment is not limited thereto. Referring to FIG. 10, the first layer 322x may be between two second layers 322y. For example, the second layer 322y may be formed along a surface of the charge blocking layer 321, the first layer 322x may be formed along a surface of the second layer 322y, and the second layer 322y may be formed along a surface of the first layer 322x. In this case, the second layer 322y may be provided on both side surfaces of the mixture layer 322′ in the second direction.

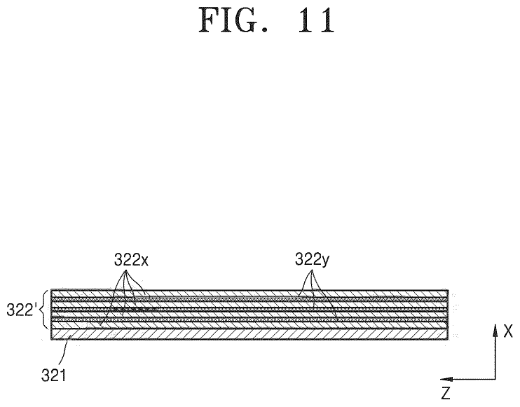

Also, referring to FIG. 11, the mixture layer 322′ may also include a plurality of first layers 322x and a plurality of second layers 322y alternately provided in the second direction. Although FIG. 11 illustrates that the first layer 322x is formed before the second layer 322y, the embodiment is not limited thereto. For example, the second layer 322y may be formed before the first layer 322x. Also, although FIG. 11 illustrates that the first layer 322x is provided on both side surfaces of the mixture layer 322′ in the second direction, the example embodiments are not limited thereto. The first layer 322x may be provided on one side surface of the mixture layer 322′ and the second layer 322y may be provided on the other side surface thereof.

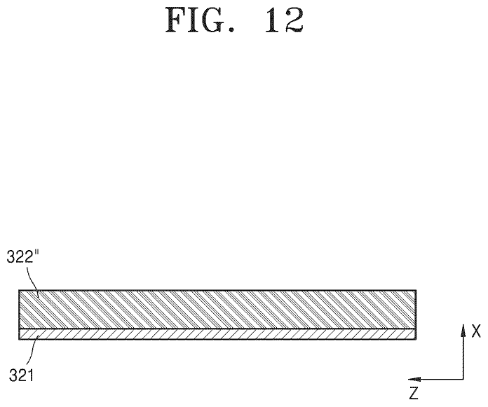

Referring to FIG. 12, the mixture layer 322″ may also be formed in which the first dielectric material, the second dielectric material, and the third dielectric material are mixed together. In this case, the first layer 322x and the second layer 322y may not be distinguished from each other. For example, the first dielectric material, the second dielectric material, and the third dielectric material may be mixed and deposited by using an ALD method by adjusting a performing ratio of an ALD cycle according to a composition ratio of each of the first dielectric material, the second dielectric material, and the third dielectric material to a total composition of the mixture layer 322″.

The size of each of the plurality of nanostructures 322NC in the charge storage layer 322 and intervals between the plurality of nanostructures 322NC may change depending on the first dielectric material, the second dielectric material, and the third dielectric material, which are actually used, and on composition ratios between the first to third dielectric materials.

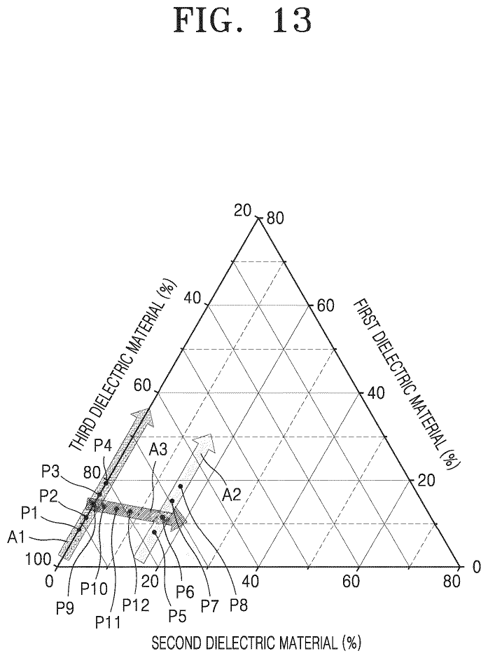

FIG. 13 is a graph illustrating an element composition ratio of the charge storage layer 322. Various samples were produced by changing a composition between a first dielectric material, a second dielectric material, and a third dielectric material as indicated by arrows A1, A2, and A3. The arrow indicated by A1 in FIG. 13 shows an example in which a composition of the second dielectric material is fixed to 0% and compositions of the first dielectric material and the third dielectric material are changed. The arrow indicated by A2 shows an example in which the composition of the second dielectric material is fixed to a percentage that is less than 20%, for example, about 18% and the compositions of the first dielectric material and the third dielectric material are changed. Also, the arrow indicated by A3 shows an example in which a composition ratio between the first dielectric material and the third dielectric material is fixed and the composition of the second dielectric material is changed.

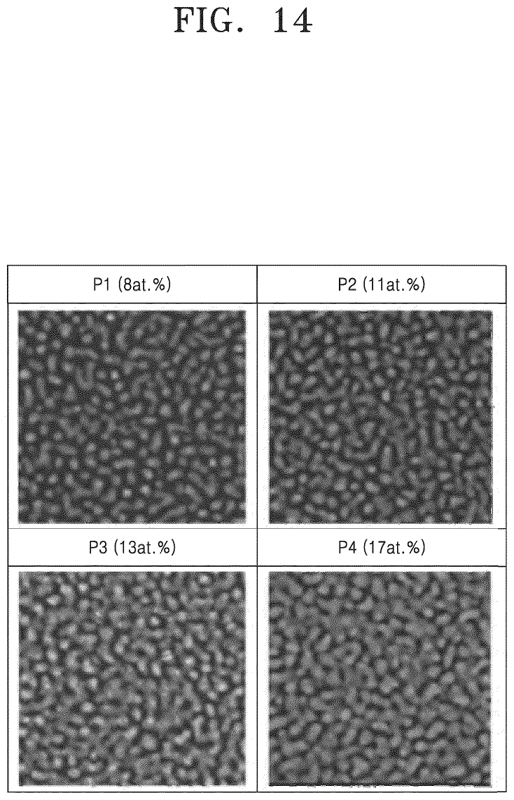

FIG. 14 illustrates high angle annular dark field scanning transmission electron microscopy (HAADF-STEM) images showing a change in distribution of the nanostructures 322NC in the matrix 322B when a composition of the charge storage layer 322 changes along the arrow indicated by A1 in FIG. 13.

Referring to FIG. 14, in a case where the second dielectric material forming the shell 322C is not in the charge storage layer 322, even when the composition of the first dielectric material increases to P1, P2, P3, and P4 on the arrow indicated by A1 in FIG. 13, a cross-sectional shape of the nanostructure 322NC may not approach a circle. In other words, when the second dielectric material is not in the charge storage layer 322, the cross-sectional shape of the nanostructure 322NC may not be close to a circle regardless of the composition of the first dielectric material. Also, the nanostructures 322NC may not be sufficiently separated from each other.

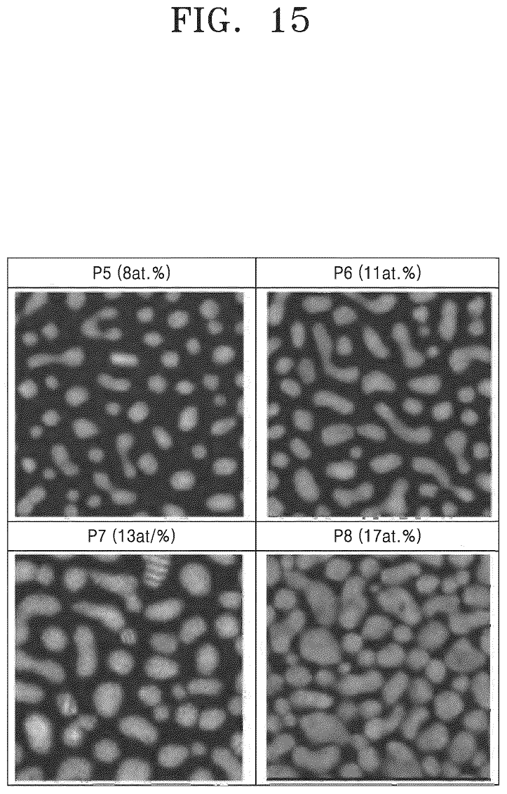

FIG. 15 illustrates HAADF-STEM images showing a change in distribution of the nanostructures 322NC in the matrix 322B when a composition of the charge storage layer 322 changes along the arrow indicated by A2 in FIG. 13. Referring to FIG. 15, when the second dielectric material forming the shell 322C is in the charge storage layer 322, a cross-sectional shape of the nanostructure 322NC may be close to a circle compared to FIG. 14. Also, the nanostructures 322NC may be clearly separated from each other. Also, as the composition of the first dielectric material increases, such as P5, P6, P7, and P8 on the arrow indicated by A2 in FIG. 13, the size of the nanostructure 322NC increases, and the cross-sectional shape of the nanostructure 322NC may be closer to a circle.

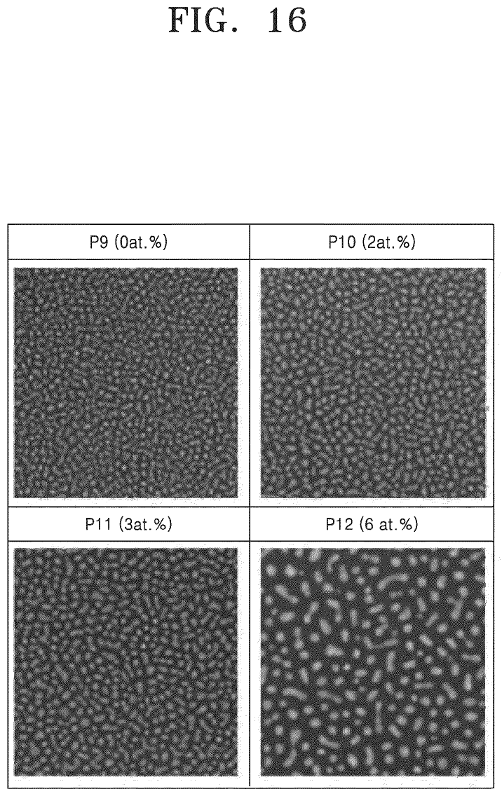

FIG. 16 illustrates HAADF-STEM images showing a change in distribution of the nanostructures 322NC in the matrix 322B when a composition of the charge storage layer 322 changes along an arrow indicated by A3 in FIG. 13. Referring to FIG. 16, as the composition of the second dielectric material forming the shell 322C increases, such as P9, P10, P11, and P12 on the arrow indicated by A3 in FIG. 13, a size of the nanostructure 322NC may increase, and intervals between the nanostructures 322NC may also increase. However, when the composition of the second dielectric material is excessively great, variability in size and shape of the nanostructure 322NC may increase.

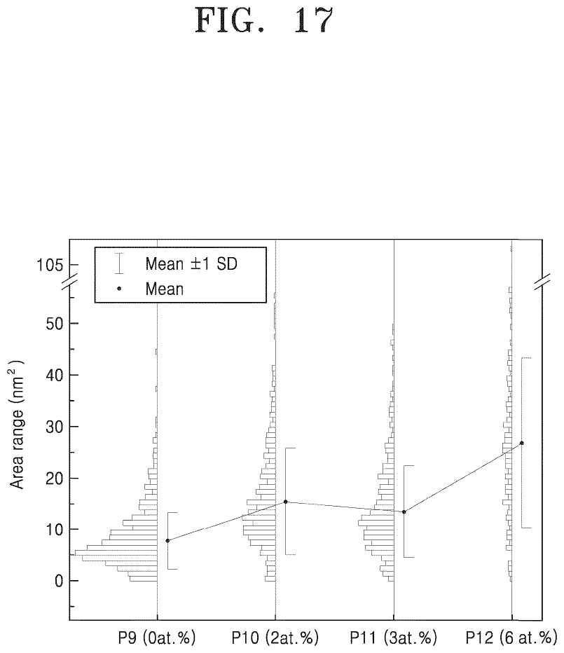

FIG. 17 is a graph illustrating distributions of cross-sectional areas of the nanostructures 322NC according to a change in composition of the charge storage layer 322. FIG. 17 illustrates a change in distribution of cross-sectional areas of the nanostructures 322NC in the matrix 322B when a composition of the charge storage layer 322 changes, particularly along the arrow indicated by A3. Referring to FIG. 17, when there is no second dielectric material, the cross-sectional areas of the nanostructures 322NC may be the smallest. When the composition of the second dielectric material is about 2 at %, an average cross-sectional area of the nanostructures 322NC increases. When the composition of the second dielectric material is about 3 at %, the average cross-sectional area of the nanostructures 322NC is slightly reduced compared to when the composition of the second dielectric material is about 2 at %, but is greater than when the composition of the second dielectric material is 0 at %. When the composition of the second dielectric material increases to 6 at %, the average cross-sectional area of the nanostructures 322NC further increases, but a standard deviation (SD) may also increase significantly.

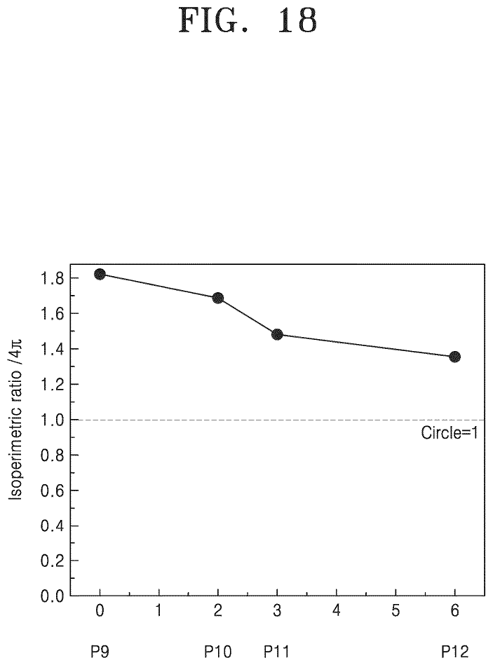

FIG. 18 is a graph illustrating a change in isoperimetric ratio of cross-sectional shapes of the nanostructures 322NC according to a change in composition of the charge storage layer 322. The isoperimetric ratio is a value (L²/A) obtained by dividing the square of a perimeter L of a cross-section by a cross-sectional area A. In FIG. 18, a vertical axis represents a value obtained by dividing the isoperimetric ratio by 4π. When a cross-sectional shape of the nanostructure 322NC is a perfect circle, the isoperimetric ratio is 4π. Therefore, the closer the average cross-sectional shape of the nanostructures 322NC is to a circle, the closer the isoperimetric ratio is to 1 of the vertical axis of FIG. 18. Referring to FIG. 18, as the composition of the second dielectric material in the charge storage layer 322 increases, the average cross-sectional shape of the nanostructure 322NC may is closer to a circle. According to at least one example embodiment, an average isoperimetric ratio of cross-sections of the plurality of nanostructures 322NC may be greater than or equal to 4π and less than or equal to 8π in a first direction (the Z direction), a second direction (the X direction), a third direction (the Y direction) perpendicular to the first and second directions, or in any other direction.

When considering the above results, a ratio of the sum of a volume of the first dielectric material and a volume of the second dielectric material to a total volume of the charge storage layer 322 may be at least about 20%. Also, the ratio of the sum of the volume of the first dielectric material and the volume of the second dielectric material to the total volume of the charge storage layer 322 may be less than or equal to about 90%, less than or equal to about 70%, or less than or equal to about 50%. In other words, a ratio of volumes of all of the plurality of nanostructures 322NC to the total volume of the charge storage layer 322, or a ratio of the sum of a total volume of the core 322A and a total volume of the shell 322C to the total volume of the charge storage layer 322 may be greater than or equal to about 20% and less than or equal to about 90%, less than or equal to about 70%, or less than or equal to about 50%.

Also, a composition ratio of the second dielectric material within the nanostructure 322NC may be less than or equal to the composition ratio of the first dielectric material. For example, a ratio of a volume of the second dielectric material to the sum of a volume of the first dielectric material and a volume of the second dielectric material may be greater than 0% and less than or equal to about 50%, less than or equal to about 40%, less than or equal to about 30%, or less than or equal to about 20%. In other words, a ratio of a volume of the shell 322C to a total volume of the nanostructure 322NC may be greater than 0% and less than or equal to about 50%, less than or equal to about 40%, less than or equal to about 30%, or less than or equal to about 20%.

In addition, spinodal decomposition may not be completely performed during the heat treatment process, in which case the nanostructure 322NC and the matrix 322B may each include a mixture of a first dielectric material, a second dielectric material, and a third dielectric material, and ratios of the first dielectric material, the second dielectric material, and the third dielectric material may be different from each other within the nanostructure 322NC and the matrix 322B. For example, the core 322A may include a mixture of the first dielectric material, the second dielectric material, and the third dielectric material, and a ratio of the first dielectric material may be the highest within the core 322A. For example, a ratio of the sum of the second dielectric material and the third dielectric material within the core 322A may be less than or equal to about 60%, less than or equal to about 50%, less than or equal to about 40%, or less than or equal to about 30%. Also, the matrix 322B may include a mixture of the first dielectric material, the second dielectric material, and the third dielectric material. A ratio of the third dielectric material may be the highest within the matrix 322B. For example, a ratio of the sum of the first dielectric material and the second dielectric material within the matrix 322B may be less than or equal to about 60%, less than or equal to about 50%, less than or equal to about 40%, or less than or equal to about 30 %.

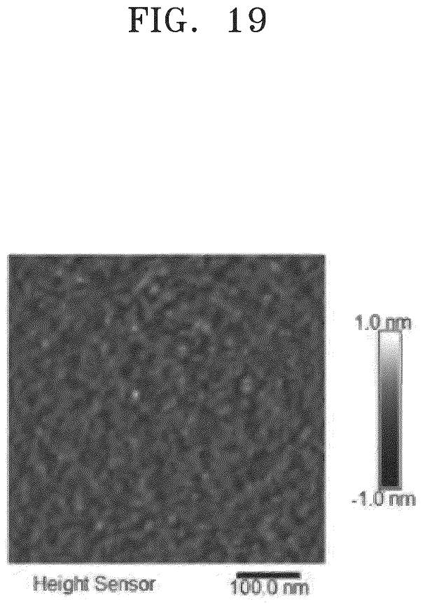

FIG. 19 is an image illustrating surface roughness of the charge storage layer 322 after heat treatment. As described above, the plurality of nanostructures 322NC may be dispersed within the matrix 322B in the charge storage layer 322 and may each be completely surrounded by the matrix 322B. Therefore, the nanostructures 322NC may not be in direct contact with the charge tunneling layer 323 and the charge blocking layer 321 adjacent to the charge storage layer 322. In other words, some of the plurality of nanostructures 322NC may not be provided on a surface or interface of the charge storage layer 322 or may not protrude outwardly from the surface of the charge storage layer 322. Accordingly, the charge storage layer 322 may have a smooth and flat surface. For example, a root mean square (RMS) value of the surface roughness of both surfaces of the charge storage layer 322 in the second direction may be less than or equal to about 2 nm or less than or equal to about 1.5 nm. A first surface among first and second surfaces of the charge storage layer 322 in the second direction may be in contact with the charge blocking layer 321, and the second surface may be in contact with the charge tunneling layer 323.

As described above, the nanostructures 322NC in the charge storage layer 322 according to at least some example embodiments may have a core-shell structure, and a cross-sectional shape of at least some of the nanostructures 322NC may be close to (e.g., substantially similar to) a circle. Therethrough, separation between the plurality of nanostructures 322NC may be more easily made. Also, compositions between the plurality of nanostructures 322NC and the matrix 322B may be clearly distinguished. As a result, charge retention characteristics within the charge storage layer 322 may be improved, and operation characteristics of the vertical nonvolatile memory device may be improved. For example, because variation of a threshold voltage is reduced in a program state, reliability and data retention of the vertical nonvolatile memory device may be improved.

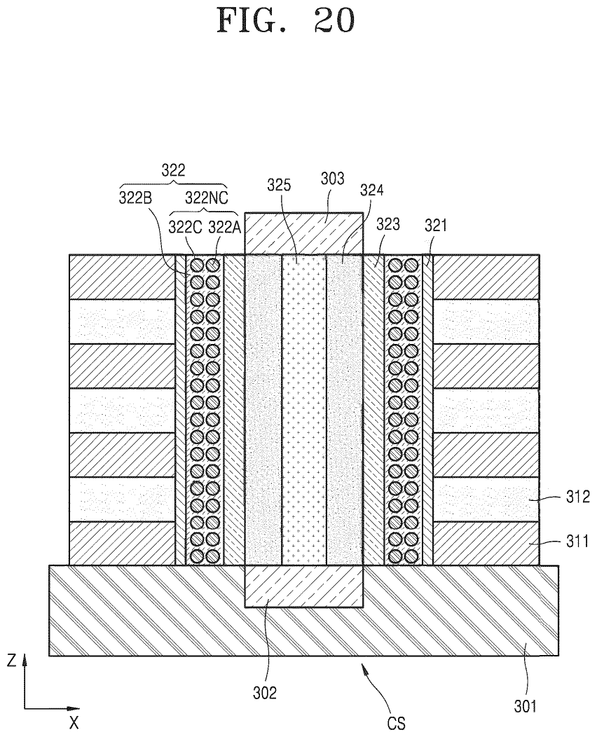

FIG. 20 is a vertical cross-sectional view schematically illustrating a structure of a memory cell string of a vertical nonvolatile memory device according to another embodiment. Although FIG. 5 illustrates that the plurality of nanostructures 322NC are distributed discontinuously and spaced apart from each other in the first direction and arranged in a single-layer structure in the second direction within the matrix 322B, the embodiment is not limited thereto. Referring to FIG. 20, a plurality of nanostructures 322NC may be arranged in a multi-layer structure in a second direction. Also, two nanostructures 322NC adjacent to each other in the second direction may be spaced apart from each other. Accordingly, the plurality of nanostructures 322NC within the matrix 322B may be distributed discontinuously and spaced apart from each other not only in the first direction but also in the second direction.

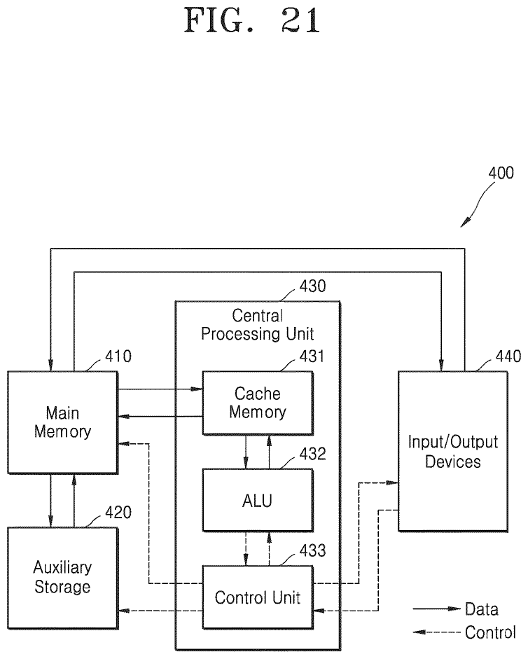

The memory device 200 described above may be used for storing data in various electronic apparatuses. FIG. 21 is a conceptual diagram schematically illustrating a device architecture that may be applied to an electronic apparatus according to at least one example embodiment. Referring to FIG. 21, an electronic apparatus 400 may include a main memory 410, an auxiliary storage 420, a central processing unit (CPU) 430, and an input/output device 440. The CPU 430 may include a cache memory 431, an arithmetic logic unit (ALU) 432, and a control unit 433. The cache memory 431 may include a static random access memory (SRAM). The main memory 410 may include a DRAM device, and the auxiliary storage 420 may include the memory device 200 according to the embodiment. Alternatively, the cache memory 431, the main memory 410, and the auxiliary storage 420 may each include the memory 200 and/or the memory system 10 according to the example embodiments. In some cases, the electronic apparatus 400 may be implemented in a form in which computing unit devices and the memory unit devices are adjacent to each other in one chip without distinction of the above-described sub-units.

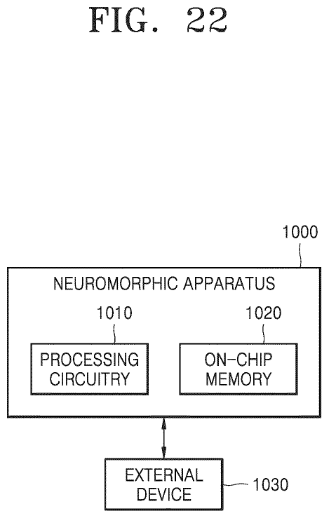

Also, the memory device 200 may be used as a neuromorphic computing platform. For example, FIG. 22 schematically illustrates a neuromorphic apparatus including the memory device 200 according to the embodiment. Referring to FIG. 22, a neuromorphic apparatus 1000 may include processing circuitry 1010 and/or a memory 1020. The memory 1020 of the neuromorphic apparatus 1000 may include the memory device 200 according to the embodiment.

The processing circuitry 1010 may control functions for driving the neuromorphic apparatus 1000. For example, the processing circuitry 1010 may control the neuromorphic apparatus 1000 by executing a program stored in the memory 1020 of the neuromorphic apparatus 1000. The processing circuitry 1010 may include hardware such as a logic circuit, a combination of software and hardware such as a processor that executes the software, or a combination thereof. For example, the processor may include a CPU, a graphics processing unit (GPU), an application processor (AP) in the neuromorphic apparatus 1000, an ALU, a digital processor, a microcontroller, a field programmable gate array (FPGA), a system-on-chip (SoC), a programmable logic unit, a microprocessor, an application-specific integrated circuit (ASIC), and/or the like. Also, the processing circuitry 1010 may read and write various data from an external device 1030 and use the data to operate the neuromorphic apparatus 1000. The external device 1030 may include a sensor array including an external memory and/or an image sensor (for example, a complementary metal-oxide semiconductor (CMOS) image sensor circuit).

The neuromorphic apparatus 1000 illustrated in FIG. 22 may be applied to a machine learning system. The machine learning system may utilize a variety of artificial neural network architectures and processing models, including, for example, a convolutional neural network (CNN), a deconvolutional neural network, a recurrent neural network (RNN) optionally including a long short-term memory (LSTM) and/or a gated recurrent unit (GRU), a stacked neural network (SNN), a state-space dynamic neural network (SSDNN), a deep belief network (DBN), a generative adversarial network (GAN), and/or a restricted Boltzmann machine (RBM).

The machine learning system may include, for example, linear regression and/or logistic regression, statistical clustering, Bayesian classification, decision trees, dimensionality reduction such as principal component analysis, and other types of machine learning models such as expert systems, and/or a combination including an ensemble technique such as random forest. The machine learning model may be used to provide various services, such as an image classification service, a user authentication service based on biometric information or biometric data, an advanced driver assistance system (ADAS), a voice assistant service, and an automatic speech recognition (ASR) service, and may be installed and executed in other electronic apparatuses.

The embodiments described above are summarized as follows.
(1) According to at least one example embodiment, a memory device includes a plurality of memory cell strings, each of the plurality of memory cell strings including a stack including a plurality of gate electrodes and a plurality of spacers alternating in a first direction, a channel layer extending in the first direction such that the channel layer faces the plurality of gate electrodes and the plurality of spacers in a second direction intersecting the first direction, and a charge storage layer extending in the first direction such that the charge storage layer is between the channel layer and the plurality of gate electrodes in the second direction and is between the channel layer and the plurality of spacers in the second direction, the charge storage layer including a matrix extending in the first direction and a plurality of nanostructures discontinuously distributed in the matrix such that the plurality of nanostructures are spaced apart from each other, wherein each of the plurality of nanostructures includes a core and a shell surrounding the core, the core includes a first dielectric material, the shell includes a second dielectric material that is different from the first dielectric material, the matrix includes a third dielectric material that is different from the first dielectric material and the second dielectric material, and the third dielectric material includes an amorphous material with a bandgap that is greater than a bandgap of the first dielectric material.
(2) The first dielectric material may include a first oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr).
(3) The second dielectric material may include a second oxide different from the first oxide, the second oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr).
(4) The third dielectric material may include at least one of an oxide, an oxynitride, or a nitride, the oxide including at least one of aluminum (Al), silicon (Si), boron (B), germanium (Ge), tin (Sn), or carbon (C), the oxynitride including at least one of aluminum (Al), silicon (Si), boron (B), germanium (Ge), tin (Sn), or carbon (C), and the nitride including at least one of aluminum (Al), silicon (Si), boron (B), germanium (Ge), tin (Sn), or carbon (C).
(5) Each of the plurality of nanostructures may have a cross-sectional diameter of 10 nm or less.
(6) An interval between adjacent two nanostructures, from the plurality of nanostructures, may be greater than or equal to 0.1 nm.
(7) An average isoperimetric ratio of cross sections of the plurality of nanostructures may be greater than or equal to 4π and less than or equal to 8π.
(8) A sum of a volume of the first dielectric material and a volume of the second dielectric material may be greater than or equal to 20% and less than or equal to 90% of a total volume of the charge storage layer.
(9) A ratio of a volume of the second dielectric material to a sum of a volume of the first dielectric material and a volume of the second dielectric material in each of the plurality of nanostructures may be greater than 0% and less than or equal to 50%.
(10) The core may include a mixture of the first dielectric material, the second dielectric material, and the third dielectric material, a composition ratio of the first dielectric material in the core is greater than a composition ratio of the second dielectric material in the core, the composition ratio of the first dielectric material in the core is greater than a composition ratio of the third dielectric material in the core, and a sum of the second dielectric material and the third dielectric material is less than or equal to 60% a total composition of the core.
(11) The matrix may include a mixture of the first dielectric material, the second dielectric material, and the third dielectric material, a composition ratio of the third dielectric material in the matrix is greater than a composition ratio of the first dielectric material in the matrix, the composition ratio of the third dielectric material in the matrix is greater than a composition ratio of the second dielectric material in the matrix, and a sum of the first dielectric material and the second dielectric material is less than or equal to 60% a total composition of the matrix.
(12) The charge storage layer may include a first surface facing the channel layer and a second surface facing the plurality of gate electrodes and the plurality of spacers, and a root mean square (RMS) value of surface roughness of the first surface and the second surface of the charge storage layer may be less than or equal to about 2 nm.
(13) Each of the plurality of memory cell strings may further include a charge blocking layer extending in the first direction such that the charge blocking layer is between the charge storage layer and the plurality of gate electrodes in the second direction and is between the charge storage layer and the plurality of spacers in the second direction;, and a charge tunneling layer extending in the first direction such that the charge tunneling layer is between the channel layer and the charge storage layer in the second direction, and each of the plurality of nanostructures may be spaced apart from the charge tunneling layer and the charge blocking layer.
(14) The plurality of nanostructures may be spaced apart from each other in the second direction and the first direction within the matrix.
(15) According to an example embodiment, a method of manufacturing a memory device includes stacking a plurality of insulating spacers and a plurality of gate electrodes in a first direction such that the plurality of gate electrodes and the plurality of insulating spacers alternate in the first direction; forming a channel hole penetrating the plurality of insulating spacers and the plurality of gate electrodes; and forming a charge storage layer and a channel layer in the channel hole such that the charge storage layer and the channel layer extend in the first direction, wherein the forming of the charge storage layer includes forming a mixture layer in the channel hole, the mixture layer including a first dielectric material, a second dielectric material which is different from the first dielectric material, and a third dielectric material which is different from the first dielectric material and the second dielectric material, and heat-treating the mixture layer to form a matrix extending in the first direction and a plurality of nanostructures distributed discontinuously in the matrix such that the plurality of nanostructures are spaced apart from each other in the first direction, each of the plurality of nanostructures includes a core and a shell surrounding the core, the core includes the first dielectric material, the shell includes the second dielectric material, the matrix includes the third dielectric material, and the third dielectric material includes an amorphous material with a bandgap that is greater than a bandgap of the first dielectric material.
(16) The forming of the mixture layer may include forming a first layer extending continuously in the first direction, and forming a second layer extending continuously in the first direction along a surface of the first layer, and the first layer may include a mixture of the first dielectric material and the third dielectric material, and the second layer may include the second dielectric material, or the first layer includes a mixture of the second dielectric material and the third dielectric layer, and the second layer may include the first dielectric material.
(17) The forming of the mixture layer may further include forming a second of the first layer to extend continuously in the first direction along a surface of the second layer such that the mixture layer includes two of the first layer and the second layer between the two first layers.
(18) In the mixture layer, a sum of the first dielectric material and the second dielectric material is 20% to 90% of a total composition of the mixture layer, and a composition ratio of the second dielectric material in the mixture layer is less than a composition ratio of the first dielectric material in the mixture layer.
(19) According to an example embodiment, an electronic apparatus includes a processing circuit, and a memory device including a plurality of memory cell strings, each of the plurality of memory cell strings including a stack including a plurality of gate electrodes and a plurality of spacers alternating in a first direction, a channel layer extending in the first direction such that the channel layer faces the plurality of gate electrodes and the plurality of spacers in a second direction intersecting the first direction, and a charge storage layer extending in the first direction such that the charge storage layer is between the channel layer and the plurality of gate electrodes in the second direction and is between the channel layer and the plurality of spacers in the second direction, the charge storage layer including a matrix extending in the first direction and a plurality of nanostructures discontinuously distributed in the matrix in the first direction such that the plurality of nanostructures are spaced apart from each other, wherein each of the plurality of nanostructures includes a core and a shell surrounding the core, the core includes a first dielectric material, the shell includes a second dielectric material that is different from the first dielectric material, and the matrix includes a third dielectric material that is different from the first dielectric material and the second dielectric material, and the third dielectric material includes an amorphous material with a bandgap that is greater than a bandgap of the first dielectric material.

As described above, a vertical nonvolatile memory device, an electronic apparatus including the vertical nonvolatile memory device, and a method of manufacturing the vertical nonvolatile memory device are described with reference to the embodiments illustrated in the drawings, but the embodiments are merely examples, and those skilled in the art will understand that various modifications and equivalent other embodiments may be derived therefrom. Therefore, the embodiments should be considered from an illustrative viewpoint rather than a limiting viewpoint. The scope of rights is indicated in the claims, not in the above description, and all differences within the scope equivalent thereto should be interpreted as being included in the scope of the rights.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a plurality of memory cell strings, each of the plurality of memory cell strings including
a stack including a plurality of gate electrodes and a plurality of spacers alternating in a first direction,
a channel layer extending in the first direction such that the channel layer faces the plurality of gate electrodes and the plurality of spacers in a second direction intersecting the first direction, and
a charge storage layer extending in the first direction such that the charge storage layer is between the channel layer and the plurality of gate electrodes in the second direction and is between the channel layer and the plurality of spacers in the second direction, the charge storage layer including a matrix extending in the first direction and a plurality of nanostructures discontinuously distributed in the matrix such that the plurality of nanostructures are spaced apart from each other,
wherein each of the plurality of nanostructures includes a core and a shell surrounding the core,
the core includes a first dielectric material,
the shell includes a second dielectric material that is different from the first dielectric material,
the matrix includes a third dielectric material that is different from the first dielectric material and the second dielectric material, and
the third dielectric material includes an amorphous material with a bandgap that is greater than a bandgap of the first dielectric material.

2. The memory device of claim 1, wherein the first dielectric material includes a first oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr).

3. The memory device of claim 2, wherein the second dielectric material includes a second oxide different from the first oxide,
the second oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr).

4. The memory device of claim 1, wherein the third dielectric material includes at least one of
an oxide including at least one of aluminum (Al), silicon (Si), boron (B), germanium (Ge), tin (Sn), or carbon (C),
an oxynitride including at least one of aluminum (Al), silicon (Si), boron (B), germanium (Ge), tin (Sn), or carbon (C), or a nitride including at least one of aluminum (Al), silicon (Si), boron (B), germanium (Ge), tin (Sn), or carbon (C).

5. The memory device of claim 1, wherein each of the plurality of nanostructures has a cross-sectional diameter of 10 nanometers (nm) or less.

6. The memory device of claim 1, wherein an interval between adjacent two nanostructures, from among the plurality of nanostructures, is greater than or equal to 0.1 nanometer (nm).

7. The memory device of claim 1, wherein an average isoperimetric ratio of cross sections of the plurality of nanostructures is greater than or equal to 4π and less than or equal to 8π.

8. The memory device of claim 1, wherein a sum of a volume of the first dielectric material and a volume of the second dielectric material is greater than or equal to 20% and less than or equal to 90% a total volume of the charge storage layer.

9. The memory device of claim 1, wherein a ratio of a volume of the second dielectric material to a sum of a volume of the first dielectric material and a volume of the second dielectric material in each of the plurality of nanostructures is greater than 0% and less than or equal to 50%.

10. The memory device of claim 1, wherein the core includes a mixture of the first dielectric material, the second dielectric material, and the third dielectric material,
a composition ratio of the first dielectric material in the core is greater than a composition ratio of the second dielectric material in the core,
the composition ratio of the first dielectric material in the core is greater than a composition ratio of the third dielectric material in the core, and
a sum of the second dielectric material and the third dielectric material is less than or equal to 60% a total composition of the core.

11. The memory device of claim 1, wherein the matrix includes a mixture of the first dielectric material, the second dielectric material, and the third dielectric material,
a composition ratio of the third dielectric material in the matrix is greater than a composition ratio of the first dielectric material in the matrix,
the composition ratio of the third dielectric material in the matrix is greater than a composition ratio of the second dielectric material in the matrix, and
a sum of the first dielectric material and the second dielectric material is less than or equal to 60% a total composition of the matrix.

12. The memory device of claim 1, wherein
the charge storage layer includes a first surface facing the channel layer and a second surface facing the plurality of gate electrodes and the plurality of spacers, and
a root mean square (RMS) value of surface roughness of the first surface and the second surface of the charge storage layer is less than or equal to about 2 nanometers (nm).

13. The memory device of claim 1, wherein each of the plurality of memory cell strings further includes:
a charge blocking layer extending in the first direction such that the charge blocking layer is between the charge storage layer and the plurality of gate electrodes in the second direction and is between the charge storage layer and the plurality of spacers in the second direction; and
a charge tunneling layer extending in the first direction such that the charge tunneling layer is between the channel layer and the charge storage layer in the second direction, and
each of the plurality of nanostructures are spaced apart from the charge tunneling layer and the charge blocking layer.

14. The memory device of claim 1, wherein the plurality of nanostructures are spaced apart from each other in the second direction and the first direction within the matrix.

15. A method of manufacturing a memory device, the method comprising:
stacking a plurality of insulating spacers and a plurality of gate electrodes in a first direction such that the plurality of gate electrodes and the plurality of insulating spacers alternate in the first direction;
forming a channel hole penetrating the plurality of insulating spacers and the plurality of gate electrodes; and
forming a charge storage layer and a channel layer in the channel hole such that the charge storage layer and the channel layer extend in the first direction,
wherein the forming of the charge storage layer includes
forming a mixture layer in the channel hole, the mixture layer including a first dielectric material, a second dielectric material which is different from the first dielectric material, and a third dielectric material which is different from the first dielectric material and the second dielectric material, and
heat-treating the mixture layer to form a matrix extending in the first direction and a plurality of nanostructures distributed discontinuously in the matrix such that the plurality of nanostructures are spaced apart from each other in the first direction,
each of the plurality of nanostructures includes a core and a shell surrounding the core,
the core includes the first dielectric material, the shell includes the second dielectric material, the matrix includes the third dielectric material, and
the third dielectric material includes an amorphous material with a bandgap that is greater than a bandgap of the first dielectric material.

16. The method of claim 15, wherein
the first dielectric material includes a first oxide, the first oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Sm), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr),
the second dielectric material includes a second oxide, different from the first oxide, the second oxide including at least one of hafnium (Hf), titanium (Ti), zirconium (Zr), uranium (U), thorium (Th), chromium (Cr), gallium (Ga), vanadium (V), scandium (Sc), ruthenium (Lu), ytterbium (Yb), erbium (Er), holmium (Ho), dysprosium (Dy), gadolinium (Gd), europium (Eu), samarium (Smi), yttrium (Y), neodymium (Nd), aluminum (Al), cerium (Ce), lanthanum (La), nickel (Ni), magnesium (Mg), copper (Cu), zinc (Zn), cobalt (Co), iron (Fe), manganese (Mn), calcium (Ca), boron (B), indium (In), thallium (Tl), or strontium (Sr), and
the third dielectric material includes at least one of a third oxide, an oxynitride, or a nitride, the third oxide including at least one of aluminum (Al), silicon (Si), boron (B), germanium (Ge), tin (Sn), or carbon (C), the oxynitride including at least one of aluminum (Al), silicon (Si), boron (B), germanium (Ge), tin (Sn), or carbon (C), and the nitride including at least one of aluminum (Al), silicon (Si), boron (B), germanium (Ge), tin (Sn), or carbon (C).

17. The method of claim 15, wherein the forming of the mixture layer includes
forming a first layer extending continuously in the first direction, and
forming a second layer extending continuously in the first direction along a surface of the first layer, and
the first layer includes a mixture of the first dielectric material and the third dielectric material and the second layer includes the second dielectric material, or the first layer includes a mixture of the second dielectric material and the third dielectric material and the second layer includes the first dielectric material.

18. The method of claim 17, wherein the forming of the mixture layer further includes forming a third layer extending continuously in the first direction along a surface of the second layer, and
the third layer includes the mixture of the first dielectric material and the third dielectric material and the second layer includes the second dielectric material, or the third layer includes the mixture of the second dielectric material and the third dielectric material and the second layer includes the first dielectric material.

19. The method of claim 15, wherein, in the mixture layer,
a sum of the first dielectric material and the second dielectric material is 20% to 90% of a total composition of the mixture layer, and
a composition ratio of the second dielectric material in the mixture layer is less than a composition ratio of the first dielectric material in the mixture layer.

20. An electronic apparatus comprising:
a processing circuit; and
a memory device including a plurality of memory cell strings, each of the plurality of memory cell strings including
a stack including a plurality of gate electrodes and a plurality of spacers alternating in a first direction,
a channel layer extending in the first direction such that the channel layer faces the plurality of gate electrodes and the plurality of spacers in a second direction intersecting the first direction, and
a charge storage layer extending in the first direction such that the charge storage layer is between the channel layer and the plurality of gate electrodes in the second direction and is between the channel layer and the plurality of spacers in the second direction, the charge storage layer including a matrix extending in the first direction and a plurality of nanostructures discontinuously distributed in the matrix in the first direction such that the plurality of nanostructures are spaced apart from each other,
wherein each of the plurality of nanostructures includes a core and a shell surrounding the core,
the core includes a first dielectric material,
the shell includes a second dielectric material that is different from the first dielectric material,
the matrix includes a third dielectric material that is different from the first dielectric material and the second dielectric material, and
the third dielectric material includes an amorphous material with a bandgap that is greater than a bandgap of the first dielectric material.
